(19) United States
(12) Patent Application Publication
(10) Pub. No.: US 2023/0085674 A1
(43) Pub. Date: Mar. 23, 2023

(54) IMAGE SENSOR, IMAGING DEVICE, AND IMAGING SYSTEM

(71) Applicant: Panasonic Intellectual Property Management Co., Ltd., Osaka (JP)

(72) Inventors: TAKAYUKI NISHITANI, Osaka (JP); SOGO OTA, Osaka (JP); YASUO MIYAKE, Osaka (JP); YOSHIHIRO SATO, Osaka (JP); KAZUKO NISHIMURA, Kyoto (JP); TSUTOMU KOBAYASHI, Osaka (JP)

(21) Appl. No.: 18/058,908

(22) Filed: Nov. 28, 2022

Related U.S. Application Data
(63) Continuation of application No. PCT/JP2021/019284, filed on May 21, 2021.

(30) Foreign Application Priority Data
Jun. 18, 2020 (JP) 2020-105604

(51) Int. Cl. H01L 27/148; H01L 27/146

(52) U.S. Cl. CPC H01L 27/14812; H01L 27/14667; H01L 27/14868; H01L 27/14612

(57) ABSTRACT

An image sensor includes a semiconductor substrate, a first photoelectric converter, and a second photoelectric converter. The semiconductor substrate has an electric-charge storage region. The second photoelectric converter is located between the first photoelectric converter and the semiconductor substrate. The first photoelectric converter includes a first counter electrode, a first pixel electrode, and a first photoelectric conversion layer. The first photoelectric conversion layer is located between the first counter electrode and the first pixel electrode. The second photoelectric converter includes a second counter electrode, a second pixel electrode, and a second photoelectric conversion layer. The second photoelectric conversion layer is located between the second counter electrode and the second pixel electrode. The electric-charge storage region is electrically connected to the first pixel electrode and the second pixel electrode.

### BACKGROUND

### 1. Technical Field

The present disclosure relates to an image sensor, an imaging device, and an imaging system.

### 2. Description of the Related Art

Various image sensors have been known. For example, an image sensor has been proposed in which one pixel has three stacked photoelectric conversion layers respectively corresponding to the wavelengths of R, G, and B (see, for example, International Publication No. WO 2016/002576).

### SUMMARY

One non-limiting and exemplary embodiment provides a technique that can help downsize an image sensor.

In one general aspect, the techniques disclosed here feature an image sensor including: a semiconductor substrate having an electric-charge storage region; a first photoelectric converter including a first counter electrode, a first pixel electrode, and a first photoelectric conversion layer located between the first counter electrode and the first pixel electrode; and a second photoelectric converter including a second counter electrode, a second pixel electrode, and a second photoelectric conversion layer located between the second counter electrode and the second pixel electrode, the second photoelectric converter being located between the first photoelectric converter and the semiconductor substrate, in which the electric-charge storage region is electrically connected to the first pixel electrode and the second pixel electrode.

The technique according to the present disclosure can help downsize an image sensor.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1A is a configuration diagram of an imaging device according to a first embodiment;

FIG. 1B is a sectional view of an image sensor according to the first embodiment;

FIG. 1C is a process diagram of a method of manufacturing the image sensor according to the first embodiment;

FIG. 1D is a process diagram of the method of manufacturing the image sensor according to the first embodiment;

FIG. 1E is a process diagram of the method of manufacturing the image sensor according to the first embodiment;

FIG. 1F is a process diagram of the method of manufacturing the image sensor according to the first embodiment;

FIG. 2A is a sectional view of an image sensor according to an example of a second embodiment;

FIG. 2B is a timing chart showing an output waveform of a variable voltage source in FIG. 2A;

FIG. 2C is a sectional view of an image sensor according to another example of the second embodiment;

FIG. 2D is a timing chart showing output waveforms of variable voltage sources in FIG. 2C;

FIG. 3 is a sectional view of an image sensor according to an example of a third embodiment;

FIG. 4A is a top view of an electrode structure of a fourth embodiment;

FIG. 4B is a top view of an electrode structure of the fourth embodiment;

FIG. 4C is a top view of an electrode structure of the fourth embodiment;

FIG. 4D is an explanatory diagram of a pixel layer array of the fourth embodiment;

FIG. 4E is a timing chart showing voltage waveforms of comb portions of the fourth embodiment;

FIG. 5 is a timing chart showing voltage waveforms of comb portions of a fifth embodiment;

FIG. 6A is an explanatory diagram of a pixel layer according to a first example of a sixth embodiment;

FIG. 6B is an explanatory diagram of a pixel layer according to a second example of the sixth embodiment;

FIG. 6C is an explanatory diagram of a pixel layer according to a third example of the sixth embodiment;

FIG. 7A is a configuration diagram of an imaging system according to a seventh embodiment;

FIG. 7B is an explanatory diagram of pixel layers of two frames according to the seventh embodiment;

FIG. 7C is an explanatory diagram of a composite frame according to the seventh embodiment;

FIG. 8A is a top view of an electrode structure of an eighth embodiment;

FIG. 8B is an explanatory diagram of pixel layers according to the eighth embodiment;

FIG. 9 is a sectional view of an image sensor according to a ninth embodiment;

FIG. 10 is a sectional view of an image sensor according to a tenth embodiment;

FIG. 11A is a sectional view of an image sensor according to an eleventh embodiment;

FIG. 11B is a top view of one pixel of the eleventh embodiment;

FIG. 11C is a top view of a plurality of pixels of the eleventh embodiment;

FIG. 12 is a sectional view of an image sensor according to a twelfth embodiment;

FIG. 13 is a schematic diagram of an image sensor of a front side illumination type;

FIG. 14 is a schematic diagram of an image sensor of a back side illumination type;

FIG. 15 is a top view of an arrangement example of specific plugs;

FIG. 16 is a top view of an arrangement example of specific plugs; and

FIG. 17 is a sectional view of a shape example of a specific plug.

### DETAILED DESCRIPTIONS

### (Underlying Knowledge of Present Disclosure)

An image sensor according to an example includes a photoelectric conversion layer, a pixel electrode, a plug, and a semiconductor substrate. The semiconductor substrate has an electric-charge storage region and a read-out circuit. The photoelectric conversion layer is connected to the pixel electrode. The pixel electrode is connected to the plug. The plug is connected to the electric-charge storage region. The photoelectric conversion layer converts light into electric charge. The electric charge is collected by the pixel electrode, sent to the electric-charge storage region via the plug, once stored in the electric-charge storage region, and then read out as a signal by the read-out circuit.

As described above, an image sensor has been proposed in which one pixel has three stacked photoelectric conversion layers respectively corresponding to the wavelengths of R, G, and B. With such an image sensor, it is possible to obtain a plurality of signals with one pixel.

In the case of a configuration of an image sensor capable of obtaining a plurality of signals with one pixel, it is conceivable that the configuration includes not only the plurality of photoelectric conversion layers but also a plurality of pixel electrodes, plugs, electric-charge storage regions, and read-out circuits. However, such a configuration is disadvantageous from the viewpoint of downsizing the image sensor.

To address this issue, the present inventors studied a technique that can help downsize an image sensor.

### (Summary of One Aspect According to Present Disclosure)

An image sensor according to a first aspect of the present disclosure includes:

a semiconductor substrate having an electric-charge storage region;

a first photoelectric converter including a first counter electrode, a first pixel electrode, and a first photoelectric conversion layer located between the first counter electrode and the first pixel electrode; and

a second photoelectric converter including a second counter electrode, a second pixel electrode, and a second photoelectric conversion layer located between the second counter electrode and the second pixel electrode, the second photoelectric converter being located between the first photoelectric converter and the semiconductor substrate, in which

the electric-charge storage region is electrically connected to the first pixel electrode and the second pixel electrode.

The technique according to the first aspect can help downsize the image sensor.

For example, in a second aspect of the image sensor according to the first aspect,

the image sensor may further include a specific plug, and

the specific plug may electrically connect the first pixel electrode, the second pixel electrode, and the electric-charge storage region.

The technique according to the second aspect can help downsize the image sensor.

For example, in a third aspect of the image sensor according to the second aspect,

the specific plug may include a first portion and a second portion,

the first portion of the specific plug may extend from the second pixel electrode toward the first pixel electrode,

the second portion of the specific plug may extend from the second pixel electrode toward the electric-charge storage region, and

an end portion of the first portion on the second pixel electrode side and an end portion of the second portion on the second pixel electrode side may be apart from each other in plan view.

The third aspect increases the degree of freedom in arrangement of the specific plug.

For example, in a fourth aspect of the image sensor according to the second or third aspect,

the specific plug may be electrically separated from the second counter electrode.

With the fourth aspect, the second photoelectric converter can operate appropriately.

For example, in a fifth aspect of the image sensor according to any one of the second to fourth aspects,

the specific plug may be located outside the outline of the second photoelectric conversion layer in a section perpendicular to the thickness direction of the second photoelectric conversion layer.

The fifth aspect eliminates the necessity of having a through hole in the second photoelectric conversion layer. This makes it easy to manufacture the image sensor, and this can in turns increase the reliability of the image sensor.

For example, in a sixth aspect of the image sensor according to any one of the second to fifth aspects,

the specific plug may include a first portion,

the first portion may extend from the first pixel electrode to the second pixel electrode,

the image sensor may include a plurality of pixels each including the electric-charge storage region, the specific plug, the first photoelectric converter, and the second photoelectric converter,

the plurality of pixels may include a first pixel and a second pixel, and in plan view,
the first pixel and the second pixel may be next to each other in a first direction, and
the position in a second direction of the first portion of the first pixel and the position in the second direction of the first portion of the second pixel may be the same.

The way of arrangement of the first portions of the specific plugs of the first pixel and the second pixel according to the sixth aspect is advantageous from the viewpoint of manufacturing the first pixel and the second pixel uniformly.

For example, in a seventh aspect of the image sensor according to any one of the second to fifth aspects,

the specific plug may include a first portion,

the first portion may extend from the first pixel electrode to the second pixel electrode,

the image sensor may include a plurality of pixels each including the electric-charge storage region, the specific plug, the first photoelectric converter, and the second photoelectric converter,

the plurality of pixels may include a first pixel and a second pixel, and

in plan view,
the first pixel and the second pixel may be next to each other in a first direction, and
the position in a second direction of the first portion of the first pixel and the position in the second direction of the first portion of the second pixel may be different.

The seventh aspect increases the degree of freedom in arrangement of the first portions.

For example, in an eighth aspect of the image sensor according to any one of the second to seventh aspects,

the specific plug may include a first portion and a second portion,

the first portion may extend from the first pixel electrode to the second pixel electrode,

the second portion of the specific plug may extend from the second pixel electrode toward the electric-charge storage region,

the sectional area of the first portion continuously may reduce in a region of the first portion including an end portion on the second pixel electrode side as the position comes closer from the first pixel electrode to the second pixel electrode, and

the sectional area of the second portion at an end portion on the second pixel electrode side may be larger than the sectional area of the first portion at the end portion on the second pixel electrode side.

The eighth aspect can contribute to increasing the overall uniformity of the sectional area of the specific plug.

For example, in a ninth aspect of the image sensor according to the eighth aspect,

the sectional area of the first portion continuously may reduce from an end portion on the first pixel electrode side to the end portion on the second pixel electrode side as the position comes closer from the first pixel electrode to the second pixel electrode.

The change in the sectional area of the first portion according to the ninth aspect is a specific example of the change in the sectional area of the first portion.

For example, in a tenth aspect of the image sensor according to the eighth or ninth aspect,

the ratio of the sectional area of the second portion at the end portion on the second pixel electrode side relative to the sectional area of the first portion at the end portion on the second pixel electrode side may be higher than 1 and lower than 1.2.

The ratio of the sectional areas according to the tenth aspect is a specific example of the ratio of the sectional areas.

For example, in an eleventh aspect of the image sensor according to any one of the second to tenth aspects,

in a case in which the length of a portion of the specific plug from the first pixel electrode to the second pixel electrode is defined as a first length, and

the length of a portion of the specific plug from the second pixel electrode to the semiconductor substrate is defined as a second length,

the first length may be longer than the second length.

The eleventh aspect is advantageous from the viewpoint of reducing the coupling between the first pixel electrode and the second pixel electrode.

For example, in a twelfth aspect of the image sensor according to any one of the second to tenth aspects,

in a case in which the length of a portion of the specific plug from the first pixel electrode to the second pixel electrode is defined as a first length, and

the length of a portion of the specific plug from the second pixel electrode to the semiconductor substrate is defined as a second length,

the first length may be shorter than the second length.

The twelfth aspect makes it easy to reduce the difference between the parasitic capacitance of the electrical path from the first pixel electrode to the electric-charge storage region and the parasitic capacitance of the electrical path from the second pixel electrode to the electric-charge storage region.

For example, in a thirteenth aspect of the image sensor according to any one of the second to twelfth aspects,

in a case in which the length of a portion of the specific plug from the first pixel electrode to the second pixel electrode is defined as a first length,

the length of a portion of the specific plug from the second pixel electrode to the semiconductor substrate is defined as a second length, and

the length of a portion of the specific plug extending inside the semiconductor substrate is defined as a third length,

the third length may be longer than the first length or the second length.

The thirteenth aspect can be advantageous from the viewpoint of arranging devices such as a photodiode in the semiconductor substrate.

For example, in a fourteenth aspect of the image sensor according to the thirteenth aspect,

the third length may be longer than the sum of the first length and the second length.

The fourteenth aspect can be advantageous from the viewpoint of arranging devices such as a photodiode in the semiconductor substrate.

For example, in a fifteenth aspect of the image sensor according to any one of the first to fourteenth aspects,

the image sensor may be of a back side illumination type.

The image sensor of the fifteenth aspect is a specific example of an image sensor.

For example, in a sixteenth aspect of the image sensor according to any one of the first to fifteenth aspects,

the first photoelectric conversion layer may generate first electric charge by photoelectric conversion,

the second photoelectric conversion layer may generate second electric charge by photoelectric conversion,

the first pixel electrode may include a first read-out electrode and a first storage electrode that causes the first photoelectric conversion layer to store the first electric charge,

the second pixel electrode may include a second read-out electrode and a second storage electrode that causes the second photoelectric conversion layer to store the second electric charge, and

the electric-charge storage region may be electrically connected to the first read-out electrode and the second read-out electrode.

The configuration of the image sensor of the sixteenth aspect is a configuration example of an image sensor.

For example, in a seventeenth aspect of the image sensor according to any one of the first to sixteenth aspects,

the first photoelectric conversion layer may perform photoelectric conversion of light in a first wavelength band, and

the second photoelectric conversion layer may perform photoelectric conversion of light in a second wavelength band.

The seventeenth aspect makes it possible to output information of the light in the first and second wavelength bands by using one specific plug and one electric-charge storage region.

An imaging device according to an eighteenth aspect of the present disclosure includes:

the image sensor according to any one of the first to seventeenth aspects; and

a voltage supply circuit that adjusts voltages of the first counter electrode and the second counter electrode.

With the eighteenth aspect, it is possible to adjust the sensitivity of the first photoelectric conversion layer to light and the sensitivity of the second photoelectric conversion layer to light.

For example, in a nineteenth aspect of the imaging device according to the eighteenth aspect,

the voltage supply circuit may include a variable voltage source connected to the first counter electrode and the second counter electrode.

The nineteenth aspect makes it easy to design a simple voltage supply circuit.

For example, in a twentieth aspect of the imaging device according to the eighteenth aspect,

the voltage supply circuit may include
a first variable voltage source connected to the second counter electrode, and
a second variable voltage source connected to the first counter electrode.

The twentieth aspect increases the degree of freedom in voltage control of the first and second photoelectric conversion layers.

For example, in a twenty-first aspect of the imaging device according to any one of the eighteenth to twentieth aspects,

the voltage supply circuit may make, by adjusting voltages of the first counter electrode and the second counter electrode,
a first state in which the photoelectric conversion in the first photoelectric conversion layer is permitted, and the photoelectric conversion in the second photoelectric conversion layer is prohibited and
a second state in which the photoelectric conversion in the first photoelectric conversion layer is prohibited, and the photoelectric conversion in the second photoelectric conversion layer is permitted.

With the twenty-first aspect, it is possible to switch between the first and second states.

For example, in a twenty-second aspect of the imaging device according to the twenty-first aspect,

the imaging device may include a plurality of pixels each including the electric-charge storage region, the first photoelectric converter, and the second photoelectric converter,

the plurality of pixels may include a first pixel and a second pixel, and

at first time,
the first pixel may be put in the first state, and
the second pixel may be put in the second state.

The twenty-second aspect can contribute to increasing the degree of freedom in reading-out of signal electric charge.

For example, in a twenty-third aspect of the imaging device according to the twenty-second aspect,

at second time,
the first pixel may be put in the second state, and
the second pixel may be put in the first state.

The twenty-third aspect can contribute to increasing the degree of freedom in reading-out of signal electric charge.

For example, in a twenty-fourth aspect of the image sensor according to any one of the first to seventeenth aspects,

the image sensor may further include a third photoelectric converter including a third counter electrode, a third pixel electrode, and a third photoelectric conversion layer located between the third counter electrode and the third pixel electrode, the third photoelectric converter being located between the second photoelectric converter and the semiconductor substrate,

the first photoelectric conversion layer may perform photoelectric conversion of light in a first wavelength band,

the second photoelectric conversion layer may perform photoelectric conversion of light in a second wavelength band,

the third photoelectric conversion layer may perform photoelectric conversion of light in a third wavelength band,

the image sensor may include a plurality of pixels each including the electric-charge storage region, the first photoelectric converter, the second photoelectric converter, and the third photoelectric converter,

the plurality of pixels may include a first pixel, a second pixel a third pixel, and a fourth pixel,

the first pixel, the second pixel, the third pixel, and the fourth pixel may form a pixel layer, and

in plan view,
the first pixel and the second pixel may be next to each other in a first direction,
the third pixel and the fourth pixel may be next to each other in the first direction,
the first pixel and the third pixel may be next to each other in a second direction, and
the second pixel and the fourth pixel may be next to each other in the second direction.

The twenty-fourth aspect makes it possible to give the sensitivity derived from at least one of the first photoelectric conversion layer, the second photoelectric conversion layer, or the third photoelectric conversion layer to each of the four adjoining pixels. The pixel layer including these pixels can achieve various kinds of imaging.

An imaging device according to a twenty-fifth aspect of the present disclosure includes:

the image sensor according to twenty-fourth aspect, and

a voltage supply circuit, in which

by changing voltages of the first counter electrode, the second counter electrode, and the third counter electrode in each of the first pixel, the second pixel, the third pixel, and the fourth pixel with the voltage supply circuit, layer rotation may be executed such that
the sensitivity to light exhibited by the first pixel in a first period is exhibited by the second pixel in a second period following the first period, exhibited by the fourth pixel in a third period following the second period, and exhibited by the third pixel in a fourth period following the third period,
the sensitivity to light exhibited by the second pixel in the first period is exhibited by the fourth pixel in the second period, exhibited by the third pixel in the third period, and exhibited by the first pixel in the fourth period,
the sensitivity to light exhibited by the fourth pixel in the first period is exhibited by the third pixel in the second period, exhibited by the first pixel in the third period, and exhibited by the second pixel in the fourth period, and
the sensitivity to light exhibited by the third pixel in the first period, exhibited by the first pixel in the second period, exhibited by the second pixel in the third period, and exhibited by the fourth pixel in the fourth period.

The twenty-fifth aspect can help provide a sharp image. The layer rotation by changing voltages makes it less likely to cause a significant increase in the size of the image sensor. This can help downsize the image sensor.

An imaging system according to a twenty-sixth aspect of the present disclosure includes:

the image sensor according to the twenty-fourth aspect or the imaging device according to the twenty-fifth aspect; and

a signal processing device, in which

the pixel layer includes a plurality of pixel layers,

in each of the pixel layers, at least one of a wavelength band of light to which the first pixel has sensitivity, a wavelength band of light to which the second pixel has sensitivity, a wavelength band of light to which the third pixel has sensitivity, or a wavelength band of light to which the fourth pixel has sensitivity is different between when a frame is generated and when a different frame is generated,

the signal processing device generates a composite frame in which the frame and the different frame are combined,

in a region of the composite frame, an image based on the frame appears, and

in another region of the composite frame, an image based on the different frame appears.

With the twenty-sixth aspect, it is possible to make a difference in the emphasized color between a region and another region.

An imaging device according to a twenty-seventh aspect of the present disclosure includes:

an image sensor; and a voltage supply circuit, in which

in the image sensor,
a first photoelectric converter, a second photoelectric converter, and a third photoelectric converter are stacked in this order,
the first photoelectric converter includes a first counter electrode, a first pixel electrode, and a first photoelectric conversion layer located between the first counter electrode and the first pixel electrode,
the second photoelectric converter includes a second counter electrode, a second pixel electrode, and a second photoelectric conversion layer located between the second counter electrode and the second pixel electrode,
the third photoelectric converter includes a third counter electrode, a third pixel electrode, and a third photoelectric conversion layer located between the third counter electrode and the third pixel electrode,
the first photoelectric conversion layer performs photoelectric conversion of light in a first wavelength band,
the second photoelectric conversion layer performs photoelectric conversion of light in a second wavelength band,
the third photoelectric conversion layer performs photoelectric conversion of light in a third wavelength band,
a plurality of pixels exist, each pixel including the first photoelectric converter, the second photoelectric converter, and the third photoelectric converter,
the plurality of pixels include a first pixel, a second pixel, a third pixel, and a fourth pixel,
the first pixel, the second pixel, the third pixel, and the fourth pixel form a pixel layer, and
in plan view,
   the first pixel and the second pixel are next to each other in a first direction,
   the third pixel and the fourth pixel are next to each other in the first direction,
   the first pixel and the third pixel are next to each other in a second direction, and
   the second pixel and the fourth pixel are next to each other in the second direction, and
in the imaging device,
by changing voltages of the first counter electrode, the second counter electrode, and the third counter electrode in each of the first pixel, the second pixel, the third pixel, and the fourth pixel with the voltage supply circuit, layer rotation is executed such that
   the sensitivity to light exhibited by the first pixel in a first period is exhibited by the second pixel in a second period following the first period, exhibited by the fourth pixel in a third period following the second period, and exhibited by the third pixel in a fourth period following the third period,
   the sensitivity to light exhibited by the second pixel in the first period is exhibited by the fourth pixel in the second period, exhibited by the third pixel in the third period, and exhibited by the first pixel in the fourth period,
   the sensitivity to light exhibited by the fourth pixel in the first period is exhibited by the third pixel in the second period, exhibited by the first pixel in the third period, and exhibited by the second pixel in the fourth period, and
   the sensitivity to light exhibited by the third pixel in the first period, exhibited by the first pixel in the second period, exhibited by the second pixel in the third period, and exhibited by the fourth pixel in the fourth period.

The twenty-seventh aspect can help provide sharp images. In addition, the layer rotation by changing voltages makes it less likely to cause a significant increase in the size of the image sensor. This can help downsize the image sensor.

An image sensor according to a twenty-eighth aspect of the present disclosure includes: a plurality of pixels each having a specific electrode, in which

the plurality of pixels include a first pixel, a second pixel, a third pixel, and a fourth pixel,

the first pixel, the second pixel, the third pixel, and the fourth pixel form a pixel layer,

in plan view,
the first pixel and the second pixel are next to each other in a first direction,
the third pixel and the fourth pixel are next to each other in the first direction,
the first pixel and the third pixel are next to each other in a second direction, and
the second pixel and the fourth pixel are next to each other in the second direction,

the image sensor includes a specific-electrode structure having a first comb portion and a second comb portion engaged with each other via a gap in the second direction and extending in the first direction and a third comb portion and a fourth comb portion engaged with each other via a gap in the second direction and extending in the first direction,

the first comb portion of the specific electrode structure has a plurality of tooth portions, one of which serves as the specific electrode of the first pixel,

the second comb portion of the specific electrode structure has a plurality of tooth portions, one of which serves as the specific electrode of the second pixel,

the third comb portion of the specific electrode structure has a plurality of tooth portions, one of which serves as the specific electrode of the third pixel,

the fourth comb portion of the specific electrode structure has a plurality of tooth portions, one of which serves as the specific electrode of the fourth pixel,

the pixel layer includes a plurality of pixel layers, and

the plurality of pixel layers are lined in the first direction.

In the twenty-eighth aspect, the comb portions make it possible to adjust, at the same time, the voltages of the plurality of specific electrodes distributed over the pixel layers and associated with one another. The configuration for adjusting the voltages at the same time by utilizing the comb shapes can contribute to downsizing the image sensor.

The image sensor according to the twenty-eighth aspect can be used for, for example, executing the layer rotation according to the twenty-fifth and twenty-seventh aspects.

Note that the specific electrode according to the twenty-eighth aspect can be used as the first counter electrode, the second counter electrode, or the third counter electrode according to the first aspect and the like. A configuration may have three specific electrodes according to the twenty-eighth aspect, which serve as the first counter electrode, the second counter electrode, and the third counter electrode, and the configuration may have three specific electrode structures, which serve as the first electrode structure, the second electrode structure, and the third electrode structure.

An image sensor according to a twenty-ninth aspect of the present disclosure includes:

a semiconductor substrate having an electric-charge storage region;

a first photoelectric converter that generates first electric charge by photoelectric conversion;

a second photoelectric converter that generates second electric charge by the photoelectric conversion;

a path to transmit the first electric charge from the first photoelectric converter to the electric-charge storage region; and

a path to transmit the second electric charge from the second photoelectric converter to the electric-charge storage region.

The technique according to the twenty-ninth aspect can help downsize the image sensor.

The techniques according to the first to twenty-ninth aspects can be mutually combined unless it causes a contradiction.

Hereinafter, embodiments according to the present disclosure will be described with reference to the drawings.

The following describes an image sensor, imaging device, and imaging system according to the embodiments with reference to the drawings.

Detailed description more than necessary may be omitted. For example, detailed description of what is already publicly known, repetitive description of substantially the same configurations, and the like may be omitted. These are to avoid a situation in which the following description is more redundant than necessary and to facilitate understanding of those skilled in the art. Note that the attached drawings and the following description are for those skilled in the art to sufficiently understand techniques according to the present disclosure, and hence these are not intended to limit the subject matters described in the claims.

In the drawings, components having substantially the same configurations, operations, and effects are denoted by the same symbols. In addition, all the numerical values mentioned below are examples for describing specifically the techniques according to the present disclosure, and thus, the techniques according to the present disclosure are not limited to the numerical values shown in those examples. Further, the connection relationships between constituents are examples for specifically describing the techniques according to the present disclosure, and hence, the connection relationships to achieve the functions of the techniques according to the present disclosure are not limited to these examples.

In this specification, ordinal numbers such as first, second, third, and so on are used in some cases. Even if a constituent has an ordinal number, it does not mean that a constituent of the same kind, having a smaller ordinal number exists. Ordinal numbers may be changed as necessary.

In this specification, a “plan view” means a view from the direction perpendicular to the semiconductor substrate. In this specification, terms such as “above”, “below”, “upper surface”, and “lower surface” are used only to specify mutual arrangement between members, and use of these terms is not intended to limit the orientation of the imaging device in use.

In this specification, “with light transmittance” means that the light transmittance of a specific wavelength band is higher than or equal to 40%. The wavelength band of visible light is, for example, from 400 nm to 780 nm. The wavelength band of near infrared light is, for example, from 780 nm to 2000 nm. Transmittance can be calculated according to the method specified in Japan Industrial Standard (JIS) R3106 (1998).

### First Embodiment

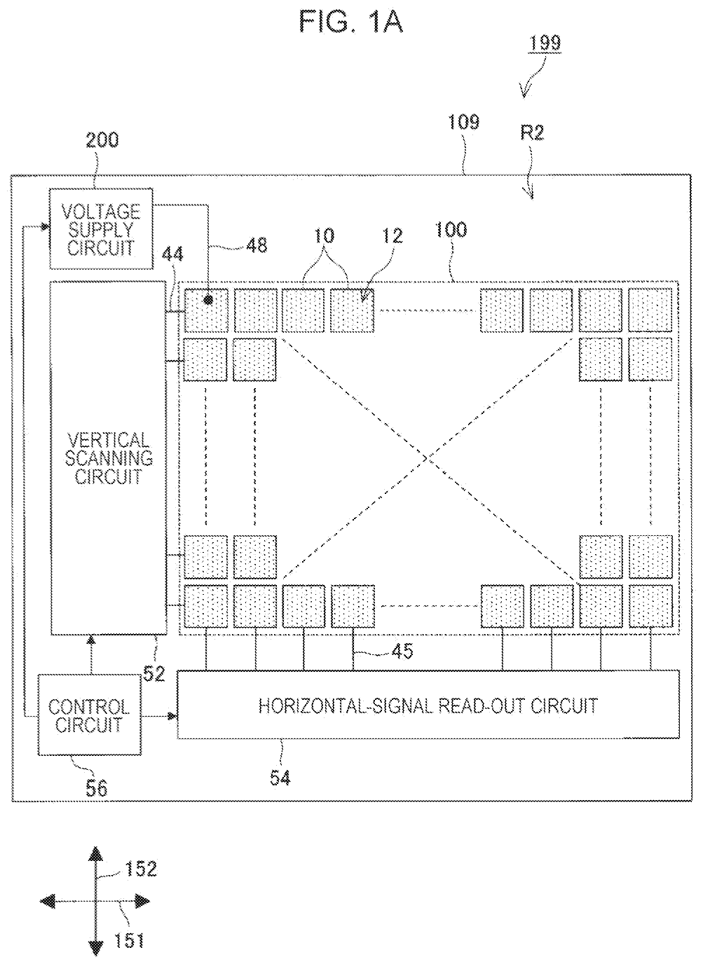

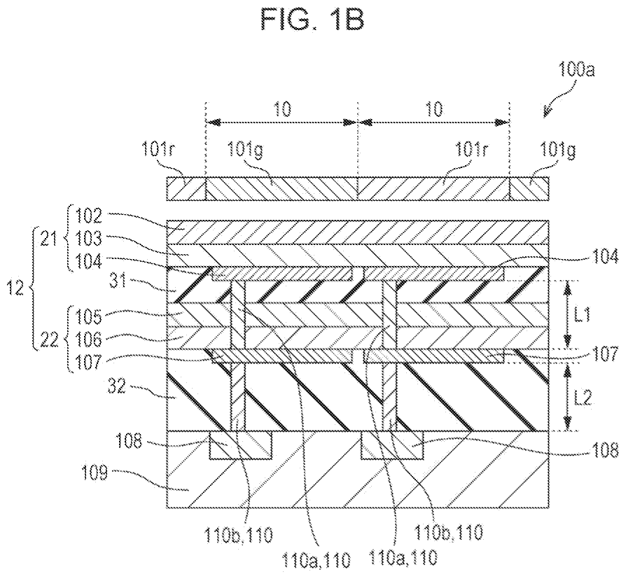

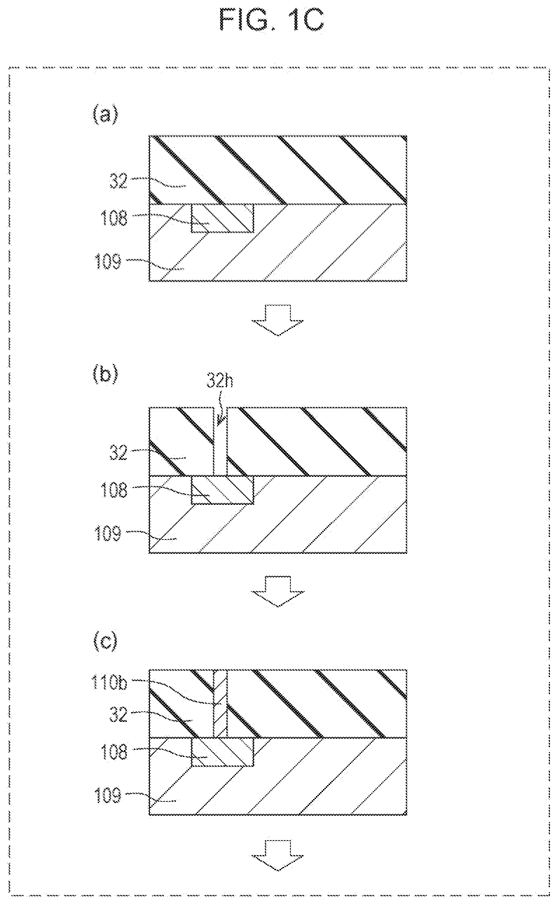

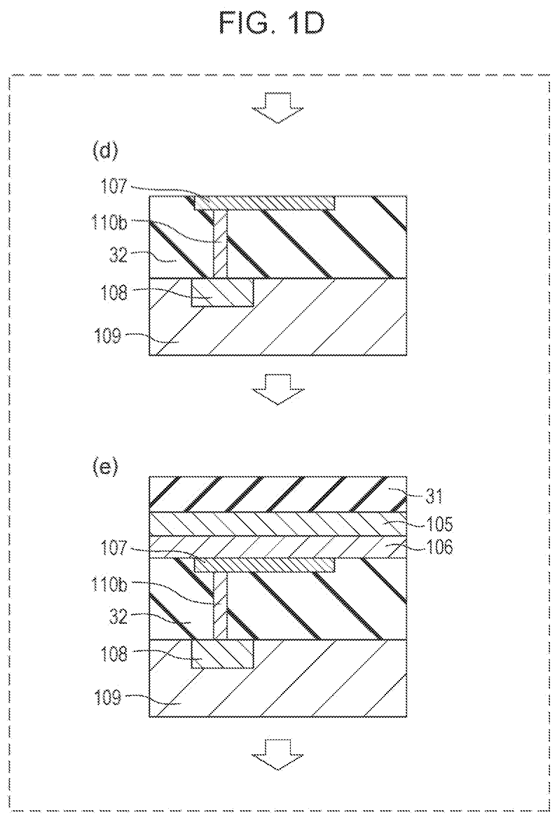

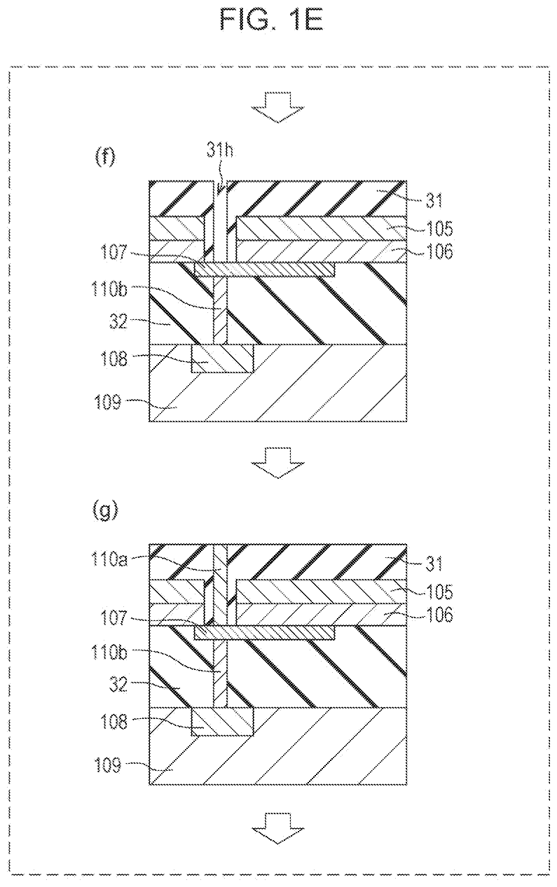

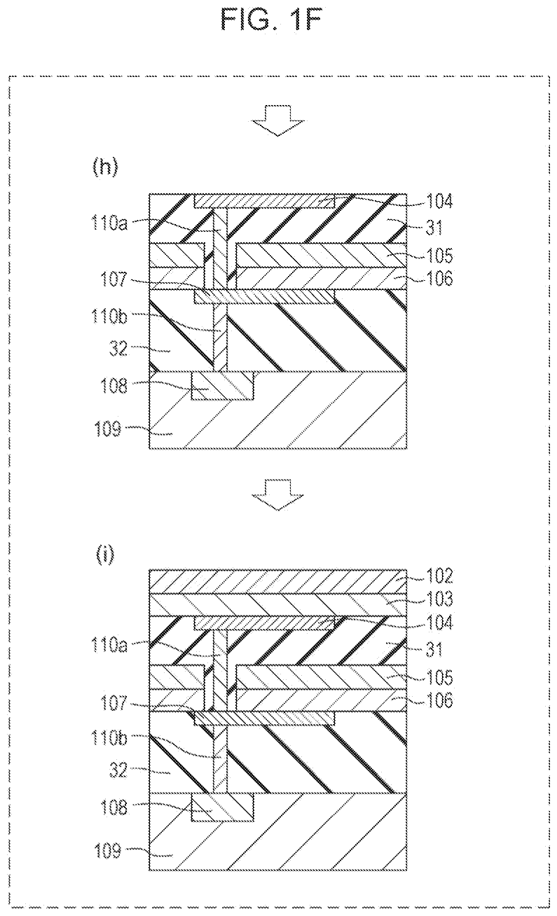

FIG. 1A shows the configuration of an imaging device 199 according to a first embodiment of the present disclosure. The imaging device 199 includes an image sensor 100. The image sensor 100 includes a semiconductor substrate 109. The image sensor 100 has a plurality of pixels 10 by using the semiconductor substrate 109.

The semiconductor substrate 109 is, for example, a Si substrate. The semiconductor substrate 109 may have various kinds of electronic circuits.

Each pixel 10 includes a photoelectric conversion region 12. The photoelectric conversion region 12 receives incident light and generates positive and negative electric charges, typically, pairs of positive hole and electron. In the illustration of FIG. 1A, the photoelectric conversion regions 12 of the pixels 10 are spatially separated from one another. However, this is only for convenience of illustration. The photoelectric conversion regions 12 of the pixels 10 may be arranged continuously on the semiconductor substrate 109 without a distance in between.

In FIG. 1A, the pixels 10 are arranged in a plurality of rows and a plurality of columns, defined as m rows and n columns. The symbols m and n are integers of one or more and are independent of each other. The pixels 10 arranged, for example, two-dimensionally form an imaging region. In plan view of the imaging device 199, the image sensor 100 may be defined as a region having a photoelectric conversion layer.

The number and arrangement of the pixels 10 are not limited to a specific number or arrangement. In FIG. 1A, the center of each pixel 10 is located on a lattice point of a square lattice. A plurality of pixels 10 may be arranged such that the center of each pixel 10 is located on a lattice point of a triangular lattice, a hexagonal lattice, or the like. The pixels 10 may be arranged one-dimensionally, and the image sensor 100 may be used as a line sensor.

The imaging device 199 has peripheral circuits provided on the semiconductor substrate 109.

The peripheral circuits include a vertical scanning circuit 52 and a horizontal-signal read-out circuit 54. The peripheral circuits may include a control circuit 56 and a voltage supply circuit 200. The peripheral circuits may further include a signal processing circuit, an output circuit, and the like. Each circuit is provided on the semiconductor substrate 109. Part of the peripheral circuits may be provided on another substrate that is different from the semiconductor substrate 109 having the pixels 10.

The vertical scanning circuit 52 is also referred to as a row scanning circuit. An address signal line 44 is provided so as to be associated with each row of the plurality of pixels 10, and the address signal lines 44 are connected to the vertical scanning circuit 52. The signal lines provided so as to be associated with the respective lines of the plurality of pixels 10 are not limited to the address signal lines 44, but a plurality of kinds of signal lines may be connected to the vertical scanning circuit 52 for each row of the pixels 10. The horizontal-signal read-out circuit 54 may be also referred to as a column scanning circuit. A vertical signal line 45 is provided so as to be associated with each column of the pixels 10, and the vertical signal lines 45 are connected to the horizontal-signal read-out circuit 54.

The control circuit 56 receives instruction data, a clock, and the like given from the outside of the imaging device 199 and controls the entire imaging device 199. Typically, the control circuit 56 has a timing generator and supplies drive signals to the vertical scanning circuit 52, the horizontal-signal read-out circuit 54, the voltage supply circuit 200, and the like. The control circuit 56 can be implemented by, for example, a micro controller including one or more processors. The functions of the control circuit 56 may be implemented by a combination of a general-purpose processing circuit and software or may be implemented by hardware dedicate to the processing described above.

The voltage supply circuit 200 supplies a specified voltage to each pixel 10 via at least one voltage line 48. The voltage supply circuit 200 is not limited to a specific power supply circuit, but may be a circuit that converts the voltage supplied from a power supply such as a battery into a specified voltage or may be a circuit that generates a specified voltage. The voltage supply circuit 200 may be part of the vertical scanning circuit 52 described above. These circuits included in the peripheral circuits may be located in a peripheral region R2 outside the image sensor 100.

FIG. 1B shows a section of an image sensor 100a which is a specific example of the image sensor 100 according to the present embodiment.

The image sensor 100a includes a semiconductor substrate 109, a first photoelectric converter 21, and a second photoelectric converter 22. The semiconductor substrate 109 has electric-charge storage regions 108. The first photoelectric converter 21 and the second photoelectric converter 22 are included in a photoelectric conversion region 12. The second photoelectric converter 22 is located between the first photoelectric converter 21 and the semiconductor substrate 109. In the example of FIG. 1B, each pixel 10 includes the semiconductor substrate 109 having an electric-charge storage region 108, the first photoelectric converter 21, and the second photoelectric converter 22.

The first photoelectric converter 21 includes a first counter electrode 102, first pixel electrodes 104, and a first photoelectric conversion layer 103. The first photoelectric conversion layer 103 is located between the first counter electrode 102 and the first pixel electrodes 104. The first counter electrode 102 is electrically connected to the first photoelectric conversion layer 103. The first pixel electrodes 104 are electrically connected to the first photoelectric conversion layer 103.

The second photoelectric converter 22 includes a second counter electrode 105, second pixel electrodes 107, and a second photoelectric conversion layer 106. The second photoelectric conversion layer 106 is located between the second counter electrode 105 and the second pixel electrodes 107. The second counter electrode 105 is electrically connected to the second photoelectric conversion layer 106. The second pixel electrodes 107 are electrically connected to the second photoelectric conversion layer 106.

Along the thickness direction of the semiconductor substrate 109, the electric-charge storage region 108, the second pixel electrodes 107, the second photoelectric conversion layer 106, the second counter electrode 105, the first pixel electrodes 104, the first photoelectric conversion layer 103, and the first counter electrode 102 are arranged in this order.

The electric-charge storage region 108 is electrically connected to the first pixel electrode 104 and the second pixel electrode 107. This configuration can help downsize the image sensor 100a. Specifically, the number of necessary electric-charge storage regions is smaller than that of the configuration in which the first pixel electrode 104 and the second pixel electrode 107 are connected to different electric-charge storage regions. Thus, the configuration in which both the first pixel electrode 104 and the second pixel electrode 107 are electrically connected to one common electric-charge storage region 108 can help downsize the image sensor 100a.

In the example of FIG. 1B, the electric charge generated by the photoelectric conversion in the first photoelectric converter 21 and the electric charge generated by the photoelectric conversion in the second photoelectric converter 22 are once stored in the electric-charge storage region 108 and then read out as signals.

In the example of FIG. 1B, the electric-charge storage region 108 is electrically connected to the first pixel electrode 104 and the second pixel electrode 107 in each pixel 10. This configuration can help downsize the pixels 10. Specifically, in the example of FIG. 1B, in each pixel 10, the electric charge generated by the photoelectric conversion in the first photoelectric converter 21 and the electric charge generated by the photoelectric conversion in the second photoelectric converter 22 are once stored in the electric-charge storage region 108 and then read out as signals. This configuration, in the case of obtaining a plurality of signals in one pixel 10, can help downsize the pixels 10.

In the example of FIG. 1B, the first read-out time to read out the electric charge generated in the first photoelectric conversion layer 103 and stored in the electric-charge storage region 108, from the electric-charge storage region 108 and the second read-out time to read out the electric charge generated in the second photoelectric conversion layer 106 and stored in the electric-charge storage region 108, from the electric-charge storage region 108 are different. Note that in this example, a trigger is not necessary to transfer electric charge from the first photoelectric conversion layer 103 to the electric-charge storage region 108. As soon as the first photoelectric conversion layer 103 is exposed to light, the electric charge is transferred from the photoelectric conversion layer 103 to the electric-charge storage region 108. This point is the same with the second photoelectric conversion layer 106. Note that in this context, the statement “a photoelectric conversion layer is exposed to light” means that the photoelectric conversion layer in a state of being ready for photoelectric conversion is exposed to light. Specifically, in the example of FIG. 1B, the statement “the photoelectric conversion layer 103 or 106 is exposed to light” means that the photoelectric conversion layer 103 or 106 is exposed to light in a state in which an appropriate voltage is being applied to the counter electrode 102 or 105.

In the case in which the second read-out is performed after the first read-out, a photoelectric conversion is performed in the second photoelectric conversion layer 106 after the first read-out and before the second read-out. In the case in which the first read-out is performed after the second read-out, a photoelectric conversion is performed in the first photoelectric conversion layer 103 after the second read-out and before the first read-out.

Specifically, the photoelectric conversion and read-out as above are performed in each pixel 10.

In the example of FIG. 1B, the image sensor 100a includes specific plugs 110. A specific plug 110 electrically connects the first pixel electrode 104, the second pixel electrode 107, and the electric-charge storage region 108. Specifically, each pixel 10 includes a specific plug 110.

The specific plug 110 is used in common for the electrical connection between the first pixel electrode 104 and the electric-charge storage region 108 and also for the electrical connection between the second pixel electrode 107 and the electric-charge storage region 108. The specific plug 110 may be referred to as a common plug.

Assume that a different plug is connected to each of the pixel electrodes 104 and 107 in one pixel 10, and that these plugs extend toward the semiconductor substrate 109. In such a case, coupling and crosstalk may occur between those plugs. In contrast, in the present embodiment, one common specific plug 110 is connected to the two electrodes, the pixel electrodes 104 and 107, and the specific plug 110 extends toward the semiconductor substrate 109. This configuration is advantageous from the viewpoint of reducing the coupling and crosstalk.

The specific plug 110 is, for example, conductor filled in a hole such as a via hole.

The specific plug 110 may be one continuous member or may have a plurality of members separated from one another.

In the present embodiment, it can be said that the image sensor 100a has a path to transmit first electric charge from the first photoelectric converter 21 to the electric-charge storage region 108 and a path to transmit second electric charge from the second photoelectric converter 22 to the electric-charge storage region 108. Note that these expressions of “has a path” are intended to mean that these paths may partially overlap.

The following further describes the constituents of the image sensor 100a.

The photoelectric conversion layers 103 and 106 are composed of a photoelectric conversion material. The photoelectric conversion material is typically an organic material. However, the photoelectric conversion material may be an inorganic material. Typically, the photoelectric conversion layers 103 and 106 have film shapes.

The first pixel electrode 104 is a transparent electrode with light transmittance to visible light and/or near infrared light. The second pixel electrode 107 may be a non-transparent electrode without light transmittance to visible light and/or near infrared light or may be a transparent electrode with light transmittance to visible light and/or near infrared light. In the case in which the second pixel electrode 107 does not have light transmittance, it is possible to prevent the electric-charge storage region 108 from receiving light. This is advantageous from the viewpoint of reducing noise. On the other hand, in the case in which the second pixel electrode 107 has light transmittance, the second pixel electrode 107 can be made of the same material as the first pixel electrode 104. This is advantageous from the viewpoint of production cost reduction.

Each of the counter electrodes 102 and 105 may be a transparent electrode with light transmittance to visible light and/or near infrared light.

The transparent electrodes and non-transparent electrodes that can be used for the pixel electrodes 104 and 107 and the counter electrodes 102 and 105 are not limited to specific ones. The transparent electrodes can be made of a transparent conductive oxide, for example, indium tin oxide (ITO). Examples of materials for non-transparent electrodes include metals, metal oxides, metal nitrides, and conductive polysilicon.

The first photoelectric conversion layer 103 performs photoelectric conversion of light in a first wavelength band. The second photoelectric conversion layer 106 performs photoelectric conversion of light in a second wavelength band. This makes it possible to output information of light in the first and second wavelength bands by using one specific plug 110 and one electric-charge storage region 108.

In the present embodiment, the electric charge corresponding to light in the first wavelength band can be generated in the first photoelectric conversion layer 103 and collected by the first pixel electrode 104. Specifically, the amount of electric charge collected by the first pixel electrode 104 depends on the voltage applied to the first counter electrode 102. The electric charge corresponding to light in the second wavelength band is generated in the second photoelectric conversion layer 106 and collected by the second pixel electrode 107. Specifically, the amount of electric charge collected by the second pixel electrode 107 depends on the voltage applied to the second counter electrode 105.

Typically, the first wavelength band and the second wavelength band are different wavelength bands. Here, the statement “the two wavelength bands are different” means a concept including not only a configuration in which the two wavelength bands do not overlap with each other but also a configuration in which the two wavelength bands overlap with each other but have different center wavelengths.

In the example of FIG. 1B, a voltage is applied to the first photoelectric conversion layer 103 by applying a potential difference between the first counter electrode 102 and the first pixel electrode 104, specifically, by applying a voltage to the first counter electrode 102. A voltage is applied to the second photoelectric conversion layer 106 by applying a potential difference between the second counter electrode 105 and the second pixel electrode 107, specifically, by applying a voltage to the second counter electrode 105.

In the example of FIG. 1B, the image sensor 100a includes color filters 101r and 101g. The light having passed through the color filter 101r is incident on the first photoelectric conversion layer 103 belonging to a pixel 10. The light having passed through the color filter 101g is incident on the first photoelectric conversion layer 103 belonging to another pixel 10.

In the present embodiment, the color filter 101g transmits green light. The color filter 101r transmits red light. The first photoelectric conversion layer 103 has sensitivity to visible light. The second photoelectric conversion layer 106 has sensitivity to infrared light.

Here, the color of light that the color filter 101r transmits is not limited to any specific one. The color of light that the color filter 101r transmits may be green, red, or blue. In these points, the same applies to the color filter 101g.

The color filters 101r and 101g may be eliminated. In the case of eliminating them, as described later in the second embodiment, the first photoelectric conversion layer 103 can employ a photoelectric conversion layer having sensitivity to green light, red light, blue light, or the like or infrared light. In this way, too, it is possible to achieve a configuration in which the first photoelectric conversion layer 103 performs photoelectric conversion of light in the first wavelength band.

The second photoelectric conversion layer 106 may employ a photoelectric conversion layer having sensitivity to green light, red light, blue light, or the like.

In the embodiment, the electric charge that the first photoelectric converter 21 (specifically, the first photoelectric conversion layer 103) generates by photoelectric conversion may be referred to as the first electric charge. The electric charge that the second photoelectric converter 22 (specifically, the second photoelectric conversion layer 106) generates by photoelectric conversion may be referred to as the second electric charge. The electric charge that a third photoelectric converter 23 (specifically, a third photoelectric conversion layer 113) described later generates by photoelectric conversion may be referred to as the third electric charge. The electric charge that a fourth photoelectric converter 24 (specifically, a fourth photoelectric conversion layer 120) described later generates by photoelectric conversion may be referred to as the fourth electric charge.

The electric-charge storage region 108 may be part of the pixel 10. In the example of FIG. 1B, the electric-charge storage regions 108 are n-type or p-type impurity regions.

The semiconductor substrate 109 may have one or a plurality of transistors to read out the electric charge stored in the electric-charge storage regions 108 and to reset the stored electric charge, for example.

A second insulation layer 32 is provided between the semiconductor substrate 109 and the second pixel electrode 107. A first insulation layer 31 is provided between the second counter electrode 105 and the first pixel electrode 104. The insulation layers 31 and 32 are composed of an insulate material such as SiO₂.

In the present embodiment, the specific plug 110 includes a first portion 110a and a second portion 110b. The first portion 110a of the specific plug 110 extends from the second pixel electrode 107 toward the first pixel electrode 104. Specifically, in the present embodiment, the first portion 110a extends from the first pixel electrode 104 to the second pixel electrode 107. The second portion 110b of the specific plug 110 extends from the second pixel electrode 107 toward the electric-charge storage region 108.

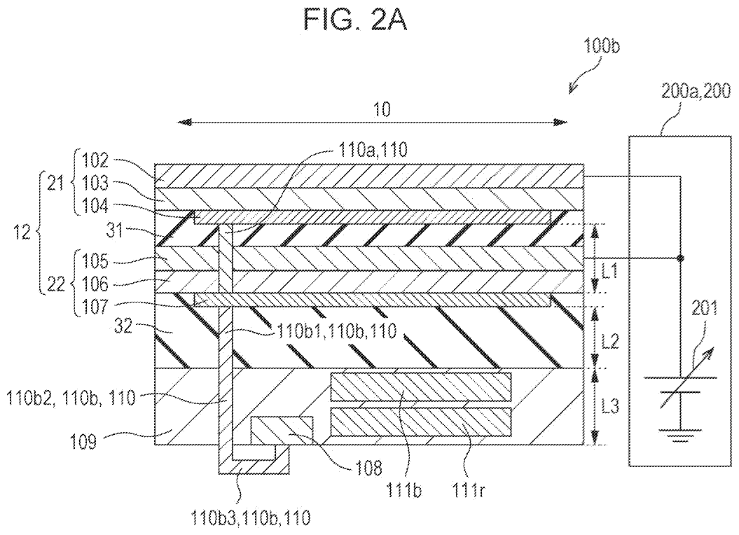

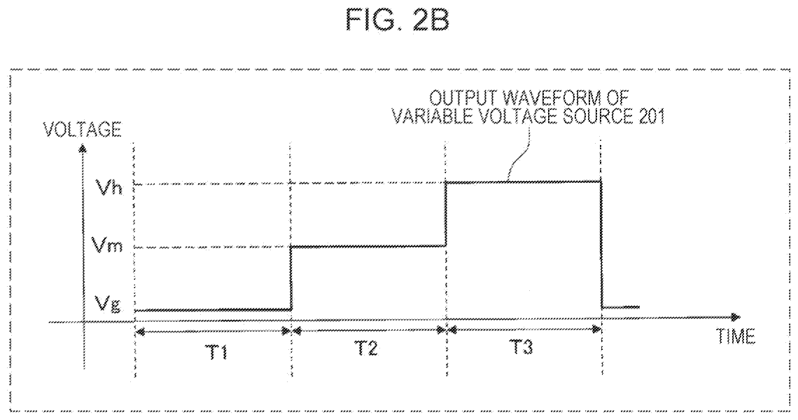

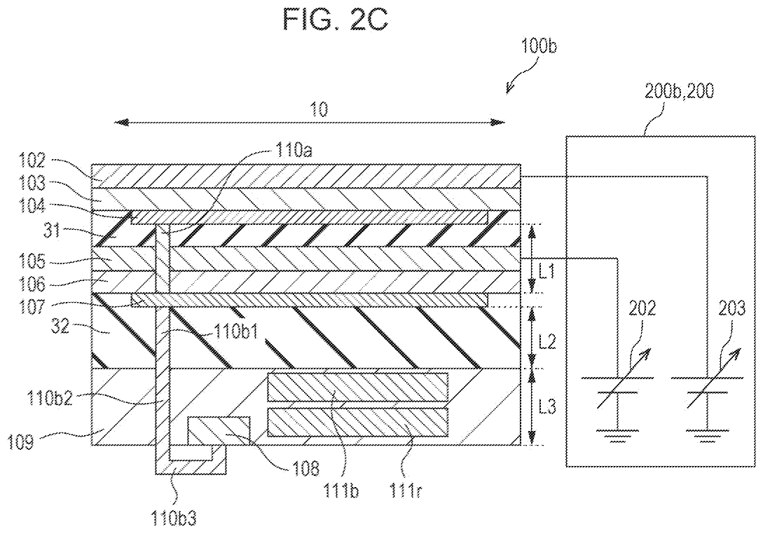

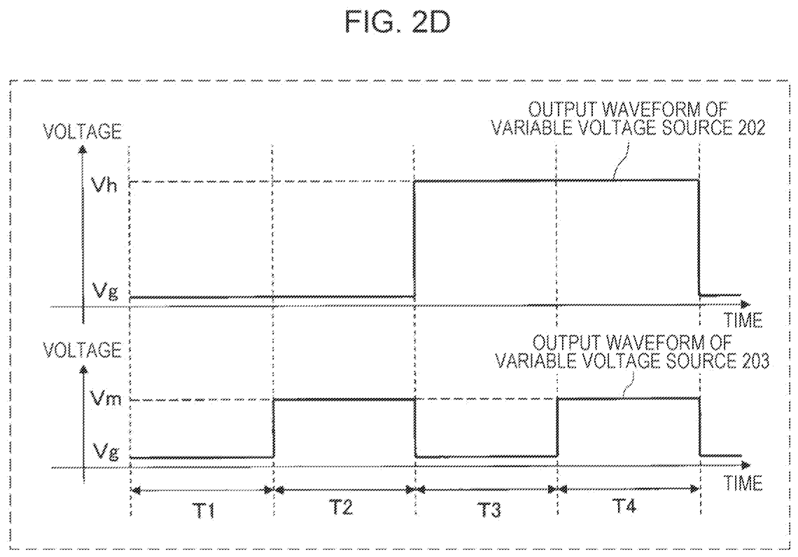

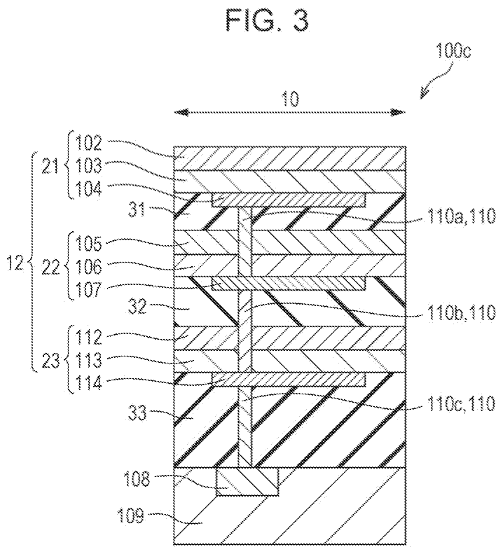

Here, a description will be given of the expression “the second portion 110b of the specific plug 110 extends from the second pixel electrode 107 toward the electric-charge storage region 108”. This expression should not be interpreted in such a limited way that it means only the configuration in which the second portion 110b extends from the second pixel electrode 107 toward the electric-charge storage region 108 in a straight line. This expression also includes the configuration in which the second portion 110b bends and extends toward the electric-charge storage region 108 as shown in FIG. 2A described later. In addition, this expression also includes the configuration in which the second portion 110b extends toward the electric-charge storage region 108 but the second portion 110b is connected to another constituent (a third pixel electrode 114 in the example of FIG. 3) as shown in FIG. 3 described later. To put it in general terms, this expression means that in the specific plug 110, the direction in which the second portion 110b extends is a direction of coming closer to the electric-charge storage region 108.

Similarly, the expression “the first portion 110a of the specific plug 110 extends from the second pixel electrode 107 toward the first pixel electrode 104” means that the direction in which the first portion 110a of the specific plug 110 extends is a direction of coming closer to the first pixel electrode 104. Similarly, the expression “a third portion 110c of the specific plug 110 described later extends from the third pixel electrode 114 toward the electric-charge storage region 108” means that the direction in which the third portion 110c of the specific plug 110 extends is a direction of coming closer to the electric-charge storage region 108.

In the example of FIG. 1B, the first portion 110a electrically connects the first pixel electrode 104 and the second pixel electrode 107. The second portion 110b electrically connects the second pixel electrode 107 and the electric-charge storage region 108.

In the example of FIG. 1B, the end portion of the first portion 110a on the second pixel electrode 107 side and the end portion of the second portion 110b on the second pixel electrode 107 side overlap with each other in plan view. Specifically, in the example of FIG. 1B, the first portion 110a and the second portion 110b overlap with each other in plan view.

In the example of FIG. 1B, the specific plug 110 extends overall in a straight line along the thickness direction of the semiconductor substrate 109. Specifically, the first portion 110a and the second portion 110b are in the forms of straight lines and extend along the above thickness direction.

The specific plug 110 is electrically separated from the second counter electrode 105. Thus, the second photoelectric converter 22 can operate appropriately.

Specifically, the second counter electrode 105 and the second photoelectric conversion layer 106 each have a through hole. The specific plug 110 passes through those through holes.

The specific plug 110 is made of a conductive material. Examples of the conductive material include metals, metal oxides, metal nitrides, and conductive polysilicon. These explanations about the specific plug 110 can be applied to the first portion 110a and the second portion 110b. These explanations about the specific plug 110 can be applied to the third portion 110c described later.

Hereinafter, the operation of the image sensor 100a will be described.

When the image sensor 100a is irradiated with light, the photoelectric conversion layers 103 and 106 each generate pairs of electron and positive hole.

When a voltage is applied between the first counter electrode 102 and the first pixel electrode 104 such that the electric potential of the first counter electrode 102 exceeds that of the first pixel electrode 104, positive holes which are positive electric charges are collected at the first pixel electrode 104, and electrons which are negative electric charges are collected at the first counter electrode 102. The positive holes collected at the first pixel electrode 104 are sent to the electric-charge storage region 108 via the specific plug 110.

When a voltage is applied between the second counter electrode 105 and the second pixel electrode 107 such that the electric potential of the second counter electrode 105 exceeds that of the second pixel electrode 107, positive holes which are positive electric charges are collected at the second pixel electrode 107, and electrons which are negative electric charges are collected at the second counter electrode 105. The positive holes collected at the second pixel electrode 107 are sent to the electric-charge storage region 108 via the specific plug 110.

The first counter electrode 102 and the second counter electrode 105 may be made as a single counter electrode. In other words, the first photoelectric converter 21 and the second photoelectric converter 22 may share a counter electrode. In that case, the second pixel electrode 107, the second photoelectric conversion layer 106, the shared counter electrode, the first photoelectric conversion layer 103, and the first pixel electrode 104 may be arranged in this order along the thickness direction of the semiconductor substrate 109.

Between a pixel electrode and a photoelectric conversion layer, a blocking layer may be provided for preventing electric charge from getting into the pixel electrode in a specific bias state.

The image sensor 100a of the present embodiment has a multilayer structure. The term “multilayer” means that the image sensor 100a has a plurality of photoelectric conversion layers in the direction normal to the semiconductor substrate 109. The multilayer structure is advantageous from the viewpoint of increasing the sensitivity of pixels because sufficient areas can be allocated to the pixel electrodes. Since the present embodiment has the two photoelectric conversion layers 103 and 106, it can be said that the image sensor 100a has a two-layer structure. The photoelectric conversion layers 103 and 106 typically have different photoelectric conversion characteristics.

Hereinafter, the manufacturing process of the image sensor 100a according to the present embodiment will be described with reference to FIGS. 1C to 1F.

First, as shown in FIG. 1C, an insulation layer is stacked on a semiconductor substrate 109 having electric-charge storage regions 108 in step (a). The insulation layer stacked in step (a) corresponds to part of the second insulation layer 32.

Next, in step (b), the insulation layer stacked in step (a) is patterned. With this process, a hole 32h is formed in the insulation layer.

Next in step (c), wiring is formed in the hole 32h formed in step (b). This wiring corresponds to the second portion 110b of the specific plug 110.

Next, as shown in FIG. 1D, in step (d), the second pixel electrode 107 is formed on the structure obtained in step (c). Note that, of the second insulation layer 32, the right and left sides of the second pixel electrode 107 in the illustration can be formed by a publicly known method.

Next, in step (e), a second photoelectric conversion layer 106, a second counter electrode 105, and an insulation layer are stacked in this order on the structure obtained in step (d). The insulation layer stacked in step (e) corresponds to part of the first insulation layer 31.

Next, as shown in FIG. 1E, the second photoelectric conversion layer 106, the second counter electrode 105, and the insulation layer stacked in step (e) are patterned in step (f). With this process, a hole 31h is formed in the second photoelectric conversion layer 106, the second counter electrode 105, and the insulation layer.

Next in step (g), wiring is formed in the hole 31h formed in step (f). This wiring corresponds to the first portion 110a of the specific plug 110.

Next, as shown in FIG. 1F, in step (h), a first pixel electrode 104 is formed on the structure obtained in step (i). Note that, of the first insulation layer 31, the right and left sides of the first pixel electrode 104 in the illustration can be formed by a publicly known method.

Next, in step (i), a first photoelectric conversion layer 103, a first counter electrode 102, and an insulation layer are stacked in this order on the structure obtained in step (h).

A description is given of downsizing the image sensor 100a by the technique in the first embodiment.

As can be understood from the above description, one specific plug 110 is shared by the plurality of pixel electrodes 104 and 107 in the first embodiment. One electric-charge storage region 108 is also used in common to store electric charges from a plurality of photoelectric conversion layers 103 and 106. These can contribute to downsizing the image sensor 100a from the viewpoint of being possible to reduce the number of plugs and the number of electric-charge storage regions. The number of read-out circuits is also reduced along with the reduction in the number of plugs and the number of electric-charge storage regions, and this point can also contribute to downsizing the image sensor 100a.

The region saved by the above sharing can be used to add other elements. Examples of such other elements include an element for noise reduction. The region saved by the above sharing can be utilized to enlarge existing elements. For example, the second embodiment described later can employ larger photodiodes. Even if other elements are added, or existing elements are enlarged, the above sharing makes the overall size of the image sensor 100a smaller than in the case of not using this sharing technique. In other words, the effect of downsizing the image sensor 100a can be obtained even in the case in which other elements are added, or existing elements are enlarged.

Hereinafter, several other embodiments will be described. In the following, the constituents common in embodiments already described and in embodiments described after that will be denoted by the same reference symbols, and description thereof may be omitted. Description of the embodiments can be applied to one another unless it causes a technical contradiction. Unless a technical contradiction occurs, the embodiments may be mutually combined.

### Second Embodiment

FIG. 2A shows an image sensor 100b according to a second embodiment. The image sensor 100b is of a back side illumination (BSI) type.

The image sensor 100b shown in FIG. 2A includes counter electrodes 102 and 105, photoelectric conversion layers 103 and 106, pixel electrodes 104 and 107, a specific plug 110, and a semiconductor substrate 109. The semiconductor substrate 109 has an electric-charge storage region 108, and photodiodes 111b and 111r.

FIG. 2A illustrates a voltage supply circuit 200. In the present embodiment, the voltage supply circuit 200 is a variable-voltage source circuit 200a. The variable-voltage source circuit 200a includes a variable voltage source 201.

In the present embodiment, the first photoelectric conversion layer 103 has sensitivity to green light. The second photoelectric conversion layer 106 has sensitivity to infrared light. The photodiode 111b has sensitivity to blue light. The photodiode 111r has sensitivity to red light.

Here, the first photoelectric conversion layer 103 may have sensitivity to green light, red light, blue light or the like or infrared light. This point is the same with the second photoelectric conversion layer 106 and the photodiodes 111b and 111r.

A configuration may be employed in which the first photoelectric conversion layer 103 has sensitivity to visible light, and the light having passed through a color filter is incident on the photoelectric conversion layer. In that case, the color of light that the color filter allows to pass is not limited to any specific one, and it may be green, red, or blue.

The second portion 110b of the specific plug 110 includes a portion 110b1, a portion 110b2, and a portion 110b3. The portion 110b1 extends in an insulation layer 32. The portion 110b2 extends in the semiconductor substrate 109. The portion 110b3 extends on the opposite side of the semiconductor substrate 109 from the insulation layer 32.

In the configuration of FIG. 2A, the output voltage of the variable voltage source 201 is applied to the counter electrodes 102 and 105. The following describes output waveforms of the variable voltage source 201 with reference to FIG. 2B.

In the period T1, the variable voltage source 201 outputs a voltage Vg. In the period T1, the first photoelectric conversion layer 103 and the second photoelectric conversion layer 106 have substantially no sensitivity. The state of having substantially no sensitivity can be described as the state in which the sensitivity is substantially zero.

In the period T2, the variable voltage source 201 outputs a voltage Vm. The voltage Vm is higher than the voltage Vg. In the period T2, the first photoelectric conversion layer 103 has sensitivity to green light. In the period T2, the second photoelectric conversion layer 106 has substantially no sensitivity.

In the period T3, the variable voltage source 201 outputs a voltage Vh. The voltage Vh is higher than the voltage Vm. In the period T3, the first photoelectric conversion layer 103 has sensitivity to green light. In the period T3, the second photoelectric conversion layer 106 has sensitivity to infrared light.

The variable-voltage source circuit 200a shown in FIG. 2A may be replaced with a variable-voltage source circuit 200b shown in FIG. 2C. The variable-voltage source circuit 200b includes a first variable voltage source 202 and a second variable voltage source 203.

In the configuration of FIG. 2C, the output voltage of the first variable voltage source 202 is applied to the second counter electrode 105, and the output voltage of the second variable voltage source 203 is applied to the first counter electrode 102. The following describes output waveforms of the first variable voltage source 202 and the second variable voltage source 203 with reference to FIG. 2D. The upper part of FIG. 2D shows an output waveform of the first variable voltage source 202. The lower part of FIG. 2D shows an output waveform of the second variable voltage source 203.

In the period T1, both the first variable voltage source 202 and the second variable voltage source 203 output the voltage Vg. In period T1, the first photoelectric conversion layer 103 and the second photoelectric conversion layer 106 have substantially no sensitivity.

In the period T2, the second variable voltage source 203 outputs the voltage Vm. In the period T2, the first photoelectric conversion layer 103 has sensitivity to green light. In the period T2, the first variable voltage source 202 outputs the voltage Vg. In the period T2, the second photoelectric conversion layer 106 has substantially no sensitivity.

In the period T3, the second variable voltage source 203 outputs the voltage Vg. In the period T3, the first photoelectric conversion layer 103 has substantially no sensitivity. In the period T3, the first variable voltage source 202 outputs the voltage Vh. In the period T3, the second photoelectric conversion layer 106 has sensitivity to infrared light.

In the period T4, the second variable voltage source 203 outputs the voltage Vm. In the period T4, the first photoelectric conversion layer 103 has sensitivity to green light. In the period T4, the first variable voltage source 202 outputs the voltage Vh. In the period T4, the second photoelectric conversion layer 106 has sensitivity to infrared light.

As can be understood from the above description, in the examples of FIGS. 2A to 2D, the voltage supply circuit 200 adjusts the voltages of the first counter electrode 102 and the second counter electrode 105. In this way, it is possible to adjust the sensitivity of the first photoelectric conversion layer 103 to the light in the first wavelength band and the sensitivity of the second photoelectric conversion layer 106 to the light in the second wavelength band.

Specifically, in the examples of FIGS. 2A to 2D, the voltage supply circuit 200 adjusts the electric potential difference between the first counter electrode 102 and the first pixel electrode 104 and the electric potential difference between the second counter electrode 105 and the second pixel electrode 107. More specifically, the voltage supply circuit 200 adjusts these electric potential differences by adjusting the voltage of the first counter electrode 102 and the voltage of the second counter electrode 105.

In the example of FIGS. 2A and 2B, the voltage supply circuit 200 has the variable voltage source 201 connected to the first counter electrode 102 and the second counter electrode 105. In the example of FIGS. 2A and 2B, the one variable voltage source 201 is used in common to apply voltages to the first counter electrode 102 and the second counter electrode 105. This configuration makes it easy to build a simple voltage supply circuit 200.

In the example of FIGS. 2C and 2D, the voltage supply circuit 200 has the first variable voltage source 202 and the second variable voltage source 203. The first variable voltage source 202 is connected to the second counter electrode 105. The second variable voltage source 203 is connected to the first counter electrode 102. The example of FIGS. 2C and 2D increases the degree of freedom in voltage control of the first photoelectric conversion layer 103 and the second photoelectric conversion layer 106.

The voltage supply circuit 200 adjusts the voltages of the first counter electrode 102 and the second counter electrode 105 to make a first state and a second state. The first state is a state in which the photoelectric conversion in the first photoelectric conversion layer 103 is permitted, and the photoelectric conversion in the second photoelectric conversion layer 106 is prohibited. The second state is a state in which the photoelectric conversion in the first photoelectric conversion layer 103 is prohibited, and the photoelectric conversion in the second photoelectric conversion layer 106 is permitted.

In an example, there are a plurality of pixels 10 each including the electric-charge storage region 108, the first photoelectric converter 21, and the second photoelectric converter 22. The plurality of pixels 10 include first and second pixels. At the first time, the first pixel is in the first state, and the second pixel is in the second state. In a specific example, in addition, at the second time, the first pixel is in the second state, and the second pixel is in the first state. This configuration can contribute to increase the degree of freedom in reading-out of signal electric charge.

Examples in FIGS. 2C and 2D are suitable for switching between the first state and the second state. In the example of FIG. 2D, the first state occurs in the period T2. The second state occurs in the period T3.

A description will be given of the aforementioned expression “a photoelectric conversion layer has substantially no sensitivity” or “the sensitivity of a photoelectric conversion layer is substantially zero”. This expression typically means that the photoelectric conversion layer does not have a practical sensitivity in terms of image forming. Designers of the image sensor 100 or the imaging device 199 can set as appropriate the voltages to be applied to the counter electrodes to make the photoelectric conversion layers have substantially no sensitivity. Although it depends on the overall configuration of the image sensor 100 or the imaging device 199, this expression, for example, means that the sensitivity is 1/10000 or less of the sensitivity in the exposure mode. Here, the exposure mode means the operation mode aimed at generation of electric charge by photoelectric conversion in the imaging device. The same applies to the expression “the photoelectric conversion in a photoelectric conversion layer is prohibited”. The expression “the photoelectric conversion in a photoelectric conversion layer is prohibited” can be replaced with the expression “a photoelectric conversion layer has substantially no sensitivity” or “the sensitivity of a photoelectric conversion layer is substantially zero”.

### Third Embodiment

FIG. 3 shows an image sensor 100c according to a third embodiment.

The image sensor 100c includes a third photoelectric converter 23, in addition to a first photoelectric converter 21 and a second photoelectric converter 22. A semiconductor substrate 109 has an electric-charge storage region 108. The first photoelectric converter 21, the second photoelectric converter 22, and the third photoelectric converter 23 are included in a photoelectric conversion region 12. The third photoelectric converter 23 is located between the second photoelectric converter 22 and the semiconductor substrate 109. Each pixel 10 may include the semiconductor substrate 109 having the electric-charge storage region 108, the first photoelectric converter 21, the second photoelectric converter 22, and the third photoelectric converter 23.

The third photoelectric converter 23 includes a third counter electrode 112, third pixel electrodes 114, and a third photoelectric conversion layer 113. The third photoelectric conversion layer 113 is located between the third counter electrode 112 and the third pixel electrodes 114. The third counter electrode 112 is electrically connected to the third photoelectric conversion layer 113. The third pixel electrodes 114 are electrically connected to the third photoelectric conversion layer 113.

Along the thickness direction of the semiconductor substrate 109, the electric-charge storage region 108, a third pixel electrode 114, a third photoelectric conversion layer 113, a third counter electrode 112, a second pixel electrode 107, a second photoelectric conversion layer 106, a second counter electrode 105, a first pixel electrode 104, a first photoelectric conversion layer 103, and a first counter electrode 102 are arranged in this order.

The electric-charge storage region 108 is electrically connected to the first pixel electrode 104, the second pixel electrode 107, and the third pixel electrode 114. The configuration in which the first pixel electrode 104, the second pixel electrode 107, and the third pixel electrode 114 are electrically connected to the one common electric-charge storage region 108 can help downsize the image sensor 100c.

In the example of FIG. 3, the electric charge generated by the photoelectric conversion in the first photoelectric converter 21, the electric charge generated by the photoelectric conversion in the second photoelectric converter 22, and the electric charge generated by the photoelectric conversion in the third photoelectric converter 23 are once stored in the electric-charge storage region 108 and then read out as signals.

In the example of FIG. 3, the electric-charge storage region 108 is electrically connected to the first pixel electrode 104, the second pixel electrode 107, and the third pixel electrode 114 in each pixel 10. Specifically, in the example of FIG. 3, in each pixel 10, the electric charge generated by the photoelectric conversion in the first photoelectric converter 21, the electric charge generated by the photoelectric conversion in the second photoelectric converter 22, and the electric charge generated by the photoelectric conversion in the third photoelectric converter 23 are once stored in the electric-charge storage region 108 and then read out as signals.

In the example of FIG. 3, the first read-out time to read out the electric charge generated in the first photoelectric conversion layer 103 and stored in the electric-charge storage region 108, from the electric-charge storage region 108, the second read-out time to read out the electric charge generated in the second photoelectric conversion layer 106 and stored in the electric-charge storage region 108, from the electric-charge storage region 108, and the third read-out time to read out the electric charge generated in the third photoelectric conversion layer 113 and stored in the electric-charge storage region 108, from the electric-charge storage region 108 are different. Note that in this example, a trigger is not necessary to transfer electric charge from the first photoelectric conversion layer 103 to the electric-charge storage region 108. As soon as the first photoelectric conversion layer 103 is exposed to light, the electric charge is transferred from the photoelectric conversion layer 103 to the electric-charge storage region 108. This point is the same with the second photoelectric conversion layer 106 and the third photoelectric conversion layer 113.

In the case in which the second read-out is performed after the first read-out, a photoelectric conversion is performed in the second photoelectric conversion layer 106 after the first read-out and before the second read-out. In the case in which the first read-out is performed after the second read-out, a photoelectric conversion is performed in the first photoelectric conversion layer 103 after the second read-out and before the first read-out. In the case in which the third read-out is performed after the second read-out, a photoelectric conversion is performed in the third photoelectric conversion layer 113 after the second read-out and before the third read-out. In the case in which the second read-out is performed after the third read-out, a photoelectric conversion is performed in the second photoelectric conversion layer 106 after the third read-out and before the second read-out. In the case in which the third read-out is performed after the first read-out, a photoelectric conversion is performed in the third photoelectric conversion layer 113 after the first read-out and before the third read-out. In the case in which the first read-out is performed after the third read-out, a photoelectric conversion is performed in the first photoelectric conversion layer 103 after the third read-out and before the first read-out.

Specifically, the photoelectric conversion and read-out as above are performed in each pixel 10.

In the example of FIG. 3, a specific plug 110 electrically connects the first pixel electrode 104, the second pixel electrode 107, the third pixel electrode 114, and the electric-charge storage region 108. Each pixel 10 may include the specific plug 110.

The specific plug 110 is used in common for the electrical connection between the first pixel electrode 104 and the electric-charge storage region 108, the electrical connection between the second pixel electrode 107 and the electric-charge storage region 108, and the electrical connection between the third pixel electrode 114 and the electric-charge storage region 108.

The following further describes the constituents of the image sensor 100c. The photoelectric conversion layers 103, 106, and 113 are composed of a photoelectric conversion material. The photoelectric conversion material is typically an organic material. However, the photoelectric conversion material may be an inorganic material. Typically, the photoelectric conversion layers 103, 106, and 113 have film shapes.

The first pixel electrode 104 is a transparent electrode with light transmittance to visible light and/or near infrared light. The second pixel electrode 107 is a transparent electrode with light transmittance to visible light and/or near infrared light. The third pixel electrode 114 may be a non-transparent electrode without light transmittance to visible light and/or near infrared light or may be a transparent electrode with light transmittance to visible light and/or near infrared light.

Each of the counter electrodes 102, 105, and 112 may be a transparent electrode with light transmittance to visible light and/or near infrared light.

The transparent electrodes and non-transparent electrodes that can be used for the pixel electrodes 104, 107, and 114 and the counter electrodes 102, 105, and 112 are not limited to specific ones. The transparent electrodes can be made of a transparent conductive oxide, for example, ITO. Examples of materials for non-transparent electrodes include metals, metal oxides, metal nitrides, and conductive polysilicon. In the present embodiment, the counter electrodes 102, 105, and 112 are ITO electrodes.

The first photoelectric conversion layer 103 performs photoelectric conversion of light in the first wavelength band. The second photoelectric conversion layer 106 performs photoelectric conversion of light in the second wavelength band. The third photoelectric conversion layer 113 performs photoelectric conversion of light in the third wavelength band.

In the present embodiment, the electric charge corresponding to light in the first wavelength band can be generated in the first photoelectric conversion layer 103 and collected by the first pixel electrode 104. Specifically, the amount of electric charge collected by the first pixel electrode 104 depends on the voltage of the first photoelectric conversion layer 103. The electric charge corresponding to light in the second wavelength band is generated in the second photoelectric conversion layer 106 and collected by the second pixel electrode 107. Specifically, the amount of electric charge collected by the second pixel electrode 107 depends on the voltage of the second photoelectric conversion layer 106. The electric charge corresponding to light in the third wavelength band is generated in the third photoelectric conversion layer 113 and collected by the third pixel electrode 114. Specifically, the amount of electric charge collected by the third pixel electrode 114 depends on the voltage of the third photoelectric conversion layer 113.

Typically, the first wavelength band, the second wavelength band, the third wavelength band are different wavelength bands.

In the example of FIG. 3, a voltage is applied to the first photoelectric conversion layer 103 by applying a potential difference between the first counter electrode 102 and the first pixel electrode 104, specifically, by applying a voltage to the first counter electrode 102. A voltage is applied to the second photoelectric conversion layer 106 by applying a potential difference between the second counter electrode 105 and the second pixel electrode 107, specifically, by applying a voltage to the second counter electrode 105. A voltage is applied to the third photoelectric conversion layer 113 by applying a potential difference between the third counter electrode 112 and the third pixel electrode 114, specifically, by applying a voltage to the third counter electrode 112.

In the present embodiment, the first photoelectric conversion layer 103 has sensitivity to blue light. The second photoelectric conversion layer 106 has sensitivity to green light. The third photoelectric conversion layer 113 has sensitivity to red light.

Here, the color of light to which the first photoelectric conversion layer 103 has sensitivity is not limited to any specific one. The color of light to which the first photoelectric conversion layer 103 has sensitivity may be blue, green, or red. These points can be applied to the second photoelectric conversion layer 106 and the third photoelectric conversion layer 113.

A third insulation layer 33 is provided between the semiconductor substrate 109 and the third pixel electrode 114. A second insulation layer 32 is provided between the third counter electrode 112 and the second pixel electrode 107. A first insulation layer 31 is provided between the second counter electrode 105 and the first pixel electrode 104. The insulation layers 31, 32, and 33 are composed of an insulation material such as SiO₂.

In the present embodiment, the specific plug 110 includes a first portion 110a, a second portion 110b, and a third portion 110c. The first portion 110a of the specific plug 110 extends from the second pixel electrode 107 toward the first pixel electrode 104. The second portion 110b of the specific plug 110 extends from the second pixel electrode 107 toward the electric-charge storage region 108. The third portion 110c of the specific plug 110 extends from the third pixel electrode 114 toward the electric-charge storage region 108.

In the example of FIG. 3, the first portion 110a electrically connects the first pixel electrode 104 and the second pixel electrode 107. The second portion 110b electrically connects the second pixel electrode 107 and the third pixel electrode 114. The third portion 110c electrically connects the third pixel electrode 114 and the electric-charge storage region 108.

In the example of FIG. 3, the first portion 110a, the second portion 110b, and the third portion 110c overlap with one another in plan view. The specific plug 110 extends overall in a straight line along the thickness direction of the semiconductor substrate 109. Specifically, the first portion 110a, the second portion 110b, and the third portion 110c are in the forms of straight lines and extend along the above thickness direction.

The specific plug 110 is electrically separated from the third counter electrode 112. The specific plug 110 is also electrically separated from the second counter electrode 105.

Specifically, the third counter electrode 112, the third photoelectric conversion layer 113, the second counter electrode 105, and the second photoelectric conversion layer 106 each have a through hole. The specific plug 110 passes through those through holes.

In the present embodiment, it can be said that the image sensor 100c has a path to transmit the first electric charge from the first photoelectric converter 21 to the electric-charge storage region 108, a path to transmit the second electric charge from the second photoelectric converter 22 to the electric-charge storage region 108, and a path to transmit the third electric charge from the third photoelectric converter 23 to the electric-charge storage region 108.

The image sensor 100c of the present embodiment has a multilayer structure. Since the present embodiment has the three photoelectric conversion layers 103, 106, and 113, it can be said that the image sensor 100a has a three-layer structure. The photoelectric conversion layers 103, 106, and 113 typically have different photoelectric conversion characteristics.

### Fourth Embodiment

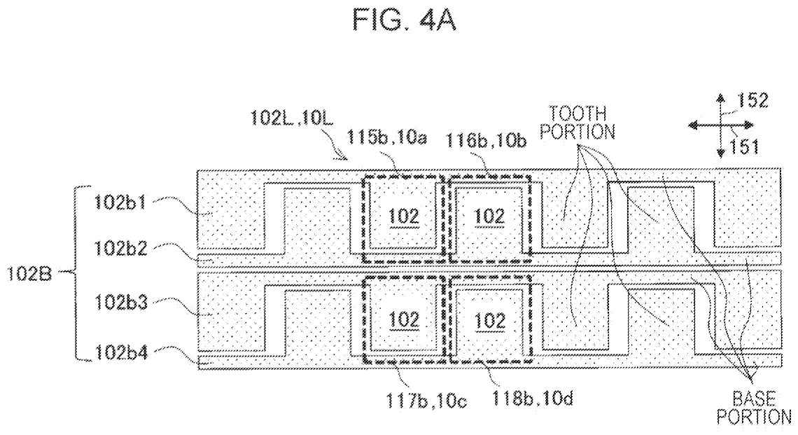

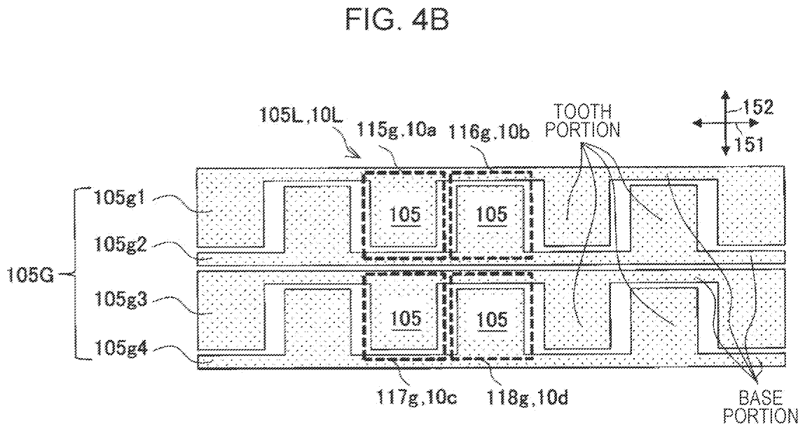

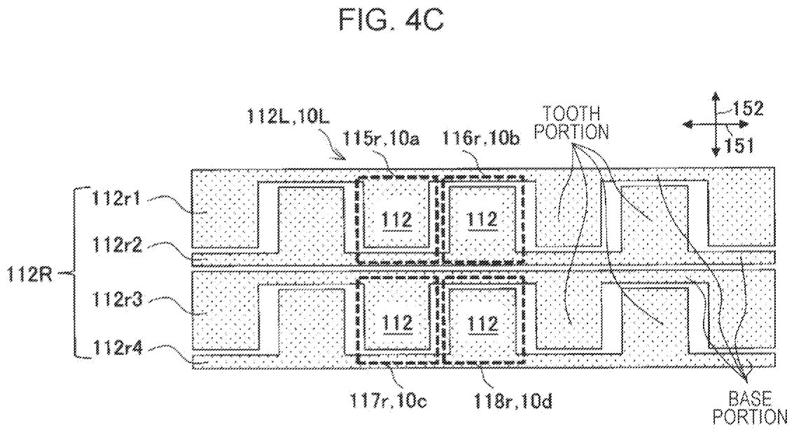

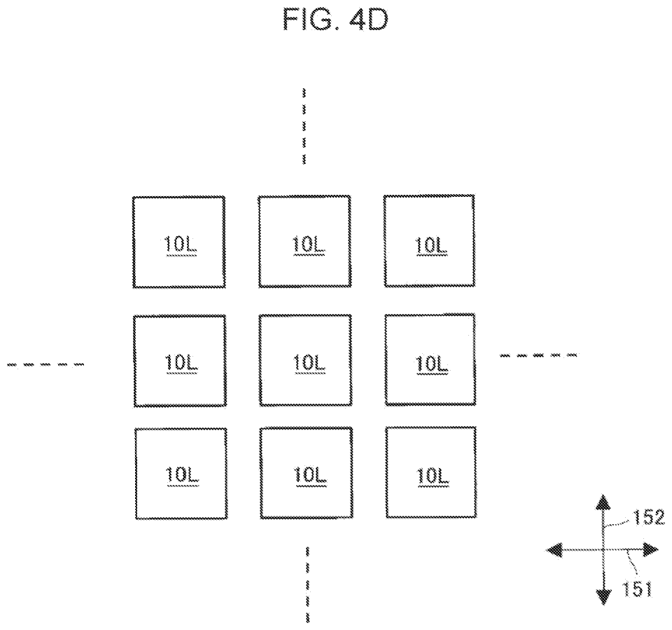

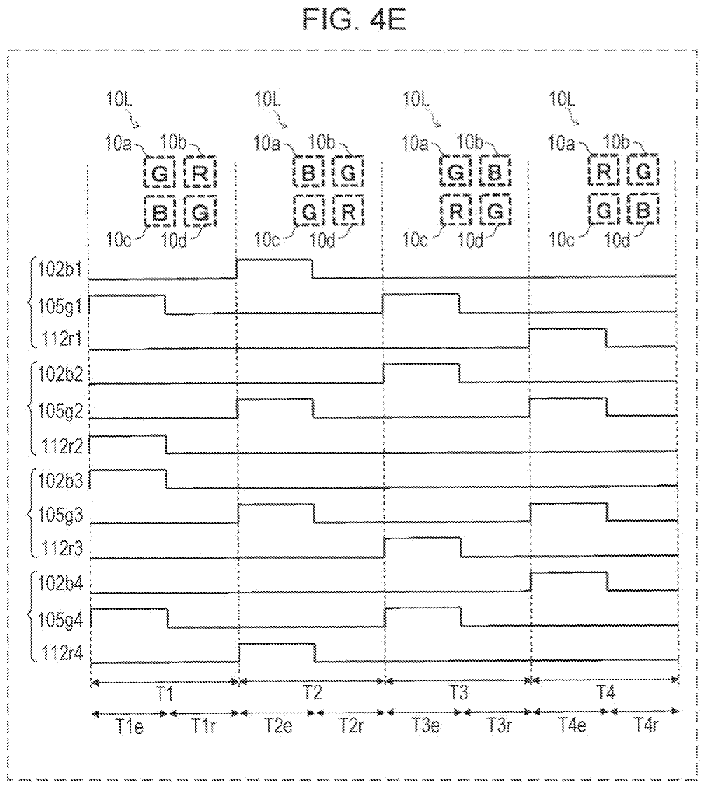

A fourth embodiment describes the configuration examples of the counter electrodes 102, 105, and 112 in the third embodiment and the way of applying voltages to the counter electrodes 102, 105, and 112 with reference to FIGS. 4A to 4E.

The present embodiment uses the terms a “first pixel 10a”, a “second pixel 10b”, a “third pixel 10c”, and a “fourth pixel 10d”. The pixels 10a, 10b, 10c, and 10d are part of the plurality of pixels 10 shown in FIG. 1. The pixels 10a, 10b, 10c, and 10d form a pixel layer 10L.

In the present embodiment, the plurality of pixels 10 each have a first photoelectric converter 21, a second photoelectric converter 22, and a third photoelectric converter 23. The pixels 10a, 10b, 10c, and 10d have the same or similar configuration.

In plan view, the first pixel 10a and the second pixel 10b are next to each other in a first direction 151. In plan view, the third pixel 10c and the fourth pixel 10d are next to each other in the first direction 151. In plan view, the first pixel 10a and the third pixel 10c are next to each other in a second direction 152. In plan view, the second pixel 10b and the fourth pixel 10d are next to each other in the second direction 152.

In the present embodiment, the counter electrodes of the pixels 10a, 10b, 10c, and 10d have an electrode structure including comb shapes. The following describes this point with reference to FIGS. 4A to 4C.

The image sensor 100c of the present embodiment has a first electrode structure 102B, a second electrode structure 105G, and a third electrode structure 112R. The first electrode structure 102B includes the first counter electrodes 102. The second electrode structure 105G includes the second counter electrodes 105. The third electrode structure 112R includes the third counter electrodes 112.

The first electrode structure 102B, the second electrode structure 105G, and the third electrode structure 112R are made by patterning. The first electrode structure 102B, the second electrode structure 105G, and the third electrode structure 112R each have a first and second comb portions that engage with each other via a gap in the second direction 152 and extend in the first direction 151 and a third and fourth comb portions that engage with each other via a gap in the second direction 152 and extend in the first direction 151.

The first direction 151 and the second direction 152 may be directions included in a plane perpendicular to the thickness direction of the semiconductor substrate 109. Specifically, the first direction 151 and the second direction 152 may be directions orthogonal to each other. In the present embodiment, the first direction 151 is the row direction. The second direction 152 is the column direction.

Specifically, as shown in FIG. 4A, the first electrode structure 102B includes a first comb portion 102b1, a second comb portion 102b2, a third comb portion 102b3, and a fourth comb portion 102b4. The first comb portion 102b1 and the second comb portion 102b2 engage with each other via a gap in the second direction 152 and extend in the first direction 151. The third comb portion 102b3 and the fourth comb portion 102b4 engage with each other via a gap in the second direction 152 and extend in the first direction 151.

As shown in FIG. 4B, the second electrode structure 105G includes a first comb portion 105g1, a second comb portion 105g2, a third comb portion 105g3, and a fourth comb portion 105g4. The first comb portion 105g1 and the second comb portion 105g2 engage with each other via a gap in the second direction 152 and extend in the first direction 151. The third comb portion 105g3 and the fourth comb portion 105g4 engage with each other via a gap in the second direction 152 and extend in the first direction 151.

As shown in FIG. 4C, the third electrode structure 112R includes a first comb portion 112r1, a second comb portion 112r2, a third comb portion 112r3, and a fourth comb portion 112r4. The first comb portion 112r1 and the second comb portion 112r2 engage with each other via a gap in the second direction 152 and extend in the first direction 151. The third comb portion 112r3 and the fourth comb portion 112r4 engage with each other via a gap in the second direction 152 and extend in the first direction 151.

Specifically, in plan view, the comb portions 102b1, 102b2, 102b3, 102b4, 105g1, 105g2, 105g3, 105g4, 112r1, 112r2, 112r3, and 112r4 each have one base portion extending in the first direction 151. The one base portion has a plurality of tooth portions extending in the second direction 152.

In the first electrode structure 102B, in plan view, a plurality of tooth portions of the comb portion 102b1 and a plurality of tooth portions of the comb portion 102b2 engage with one another via a gap. In plan view, a plurality of tooth portions of the comb portion 102b3 and a plurality of tooth portions of the comb portion 102b4 engage with one another via a gap.

In the second electrode structure 105G, in plan view, a plurality of tooth portions of the comb portion 105g1 and a plurality of tooth portions of the comb portion 105g2 engage with one another via a gap. In plan view, a plurality of tooth portions of the comb portion 105g3 and a plurality of tooth portions of the comb portion 105g4 engage with one another via a gap.

In the third electrode structure 112R, in plan view, a plurality of tooth portions of the comb portion 112r1 and a plurality of tooth portions of the comb portion 112r2 engage with one another via a gap. In plan view, a plurality of tooth portions of the comb portion 112r3 and a plurality of tooth portions of the comb portion 112r4 engage with one another via a gap.

In the present embodiment, the first comb portion 102b1, the second comb portion 102b2, the third comb portion 102b3, and the fourth comb portion 102b4 are electrically separated from one another. The first comb portion 105g1, the second comb portion 105g2, the third comb portion 105g3, and the fourth comb portion 105g4 are electrically separated from one another. The first comb portion 112r1, the second comb portion 112r2, the third comb portion 112r3, and the fourth comb portion 112r4 are electrically separated from one another.

In FIGS. 4A to 4C, the regions 115b, 115g, and 115r show the region in which a first pixel 10a extends. The regions 116b, 116g, and 116r show the region in which a second pixel 10b extends. The regions 117b, 117g, and 117r show the region in which a third pixel 10c extends. The regions 118b, 118g, and 118r show the region in which a fourth pixel 10d extends.

In FIGS. 4A to 4C, a region 102L, a region 105L, and a region 112L show the region in which the pixel layer 10L extends. The region 102L includes the region 115b, the region 116b, the region 117b, and the region 118b. The region 105L includes the region 115g, the region 116g, the region 117g, and the region 118g. The region 112L includes the region 115r, the region 116r, the region 117r, and the region 118r.

One of the tooth portions of the first comb portion 102b1 in the first electrode structure 102B serves as the first counter electrode 102 of the first pixel 10a. One of the tooth portions of the first comb portion 105g1 in the second electrode structure 105G serves as the second counter electrode 105 of the first pixel 10a. One of the tooth portions of the first comb portion 112r1 in the third electrode structure 112R serves as the third counter electrode 112 of the first pixel 10a.

One of the tooth portions of the second comb portion 102b2 in the first electrode structure 102B serves as the first counter electrode 102 of the second pixel 10b. One of the tooth portions of the second comb portion 105g2 in the second electrode structure 105G serves as the second counter electrode 105 of the second pixel 10b. One of the tooth portions of the second comb portion 112r2 in the third electrode structure 112R serves as the third counter electrode 112 of the second pixel 10b.

One of the tooth portions of the third comb portion 102b3 in the first electrode structure 102B serves as the first counter electrode 102 of the third pixel 10c. One of the tooth portions of the third comb portion 105g3 in the second electrode structure 105G serves as the second counter electrode 105 of the third pixel 10c. One of the tooth portions of the third comb portion 112r3 in the third electrode structure 112R serves as the third counter electrode 112 of the third pixel 10c.

One of the tooth portions of the fourth comb portion 102b4 in the first electrode structure 102B serves as the first counter electrode 102 of the fourth pixel 10d. One of the tooth portions of the fourth comb portion 105g4 in the second electrode structure 105G serves as the second counter electrode 105 of the fourth pixel 10d. One of the tooth portions of the fourth comb portion 112r4 in the third electrode structure 112R serves as the third counter electrode 112 of the fourth pixel 10d.

In each of the first pixel 10a, the second pixel 10b, the third pixel 10c, and the fourth pixel 10d in plan view, the first counter electrode 102, the second counter electrode 105, and the third counter electrode 112 are layered on top of each other.

As shown in FIG. 4D, there are a plurality of pixel layers 10L. The plurality of pixel layers 10L are lined in the first direction 151.

In the example of FIG. 4D, the plurality of pixel layers 10L are also lined in the second direction 152. Specifically, the plurality of pixel layers 10L are arrayed in the first and second directions 151 and 152.

In the present embodiment, the voltage of the plurality of counter electrodes distributed over the pixel layers 10L and associated with one another can be adjusted at the same time by applying a voltage to the comb portion. The configuration of adjusting the voltages at the same time by utilizing the comb shapes can contribute to downsizing the image sensor.

The following describes the waveforms of voltages applied to the comb portions 102b1, 102b2, 102b3, 102b4, 105g1, 105g2, 105g3, 105g4, 112r1, 112r2, 112r3, and 112r4 with reference to FIG. 4E.

In FIG. 4E, the period T1, the period T2, the period T3, and the period T4 occur in this order. The period T1 corresponds to a first frame. The period T2 corresponds to a second frame. The period T3 corresponds to a third frame. The period T4 corresponds to a fourth frame. In other words, the images of the first frame, the second frame, the third frame, and the fourth frame are in this order in time series.

The period T1 includes an exposure period T1e and a read-out period T1r in this order. The period T2 includes an exposure period T2e and a read-out period T2r in this order. The period T3 includes an exposure period T3e and a read-out period T3r in this order. The period T4 includes an exposure period T4e and a read-out period T4r in this order.

In the exposure period T1e, voltages are applied to the comb portions 105g1, 112r2, 102b3, and 105g4. Thus, the first pixel 10a and the fourth pixel 10d have sensitivity to green light. The second pixel 10b has sensitivity to red light. The third pixel 10c has sensitivity blue light. In the read-out period T1r, the electric charges stored in the electric-charge storage regions 108 in the exposure period T1e are read out as signals.

In the exposure period T2e, voltages are applied to the comb portions 102b1, 105g2, 105g3, and 112r4. Thus, the first pixel 10a has sensitivity to blue light. The second pixel 10b and the third pixel 10c have sensitivity to green light. The fourth pixel 10d has sensitivity to red light. In the read-out period T2r, the electric charges stored in the electric-charge storage regions 108 in the exposure period T2e are read out as signals.

In the exposure period T3e, voltages are applied to the comb portions 105g1, 102b2, 112r3, and 105g4. Thus, the first pixel 10a and the fourth pixel 10d have sensitivity to green light. The second pixel 10b has sensitivity to blue light. The third pixel 10c has sensitivity red light. In the read-out period T3r, the electric charges stored in the electric-charge storage regions 108 in the exposure period T3e are read out as signals.

In the exposure period T4e, voltages are applied to the comb portions 112r1, 105g2, 105g3, and 102b4. Thus, the first pixel 10a has sensitivity to red light. The second pixel 10b and the third pixel 10c have sensitivity to green light. The fourth pixel 10d has sensitivity to blue light. In the read-out period T4r, the electric charges stored in the electric-charge storage regions 108 in the exposure period T4e are read out as signals.

Through the four frames from the period T1 to the period T4, the layer arrangement can be rotated.

The rotation of the layer arrangement can help provide clear images. The following describes this point.

In the present embodiment, in one pixel 10, the period in which photoelectric conversion is performed in the first photoelectric conversion layer 103, the period in which photoelectric conversion is performed in the second photoelectric conversion layer 106, and the period in which photoelectric conversion is performed in the third photoelectric conversion layer 113 are different. In addition, the period in which the electric charge obtained by the photoelectric conversion in the first photoelectric conversion layer 103 is read out from the electric-charge storage region 108, the period in which the electric charge obtained by the photoelectric conversion in the second photoelectric conversion layer 106 is read out from the electric-charge storage region 108, and the period in which the electric charge obtained by the photoelectric conversion in the third photoelectric conversion layer 113 is read out from the electric-charge storage region 108 are also different. Hence, the signals read out have information of different colors but are information pieces at times shifted from one another. In this case, it is possible to generate the frame reflecting color information derived from the first photoelectric conversion layer 103, the frame reflecting color information derived from the second photoelectric conversion layer 106, and the frame reflecting color information derived from the third photoelectric conversion layer 113. However, if these frames were combined, the image would look blurred because of the difference in the time of the color information. In other words, the image would be unclear. Even if image processing is performed in a subsequent stage of the image sensor, it would not be easy to completely solve this problem.

To address this in the present embodiment, the sensitivities of the four pixels 10a, 10b, 10c, and 10d to light are adjusted in the one pixel layer 10L such that these pixels exhibit sensitivities to three colors in the same period. Thus, one frame can reflect information of the three colors derived from the photoelectric conversion layers 103, 106, 20 and 113. In addition, in the one pixel layer 10L, the sensitivities that the four pixels 10a, 10b, 10d, and 10c exhibit transition in four kinds in this order sequentially in a loop. Since this sensitivity transition occurs every time the frame changes, this provides a visual effect that stabilizes the colors of the one pixel layer 10L. For example, in video, when the frame switching with such sensitivity transition is performed quickly and continuously, human eyes see it in such a way that the color tone appears to be stable rather than that the sensitivity is changing among the four kinds. In addition, in the case of combining four kinds of consecutive frames in time series to generate a composite frame, human eyes see it in such a way that the color tone of the composite frame is stable. Thus, the rotation of the layer arrangement makes it possible to provide clear images.

As can be understood from the above description, the present embodiment involves execution of the layer rotation. The following describes the layer rotation in the present embodiment. In the following description, the terms “the first period”, “the second period”, “the third period”, and “the fourth period” may be used. The second period is a period following the first period. The third period is a period following the second period. The fourth period is a period following the third period.

In the present embodiment, the layer rotation is executed by changing the voltages of the first photoelectric conversion layer 103, the second photoelectric conversion layer 106, and the third photoelectric conversion layer 113 in each of the first pixel 10a, the second pixel 10b, the third pixel 10c, and the fourth pixel 10d.

The sensitivity to light exhibited by the first pixel 10a in the first period is defined as a first sensitivity. The layer rotation is executed in such a way that the second pixel 10b exhibits the first sensitivity in the second period, that the fourth pixel 10d exhibits the first sensitivity in the third period, and that the third pixel 10c exhibits the first sensitivity in the fourth period.

The sensitivity to light exhibited by the second pixel 10b in the first period is defined as a second sensitivity. The layer rotation is executed in such a way that the fourth pixel 10d exhibits the second sensitivity in the second period, that the third pixel 10c exhibits the second sensitivity in the third period, and that the first pixel 10a exhibits the second sensitivity in the fourth period.

The sensitivity to light exhibited by the fourth pixel 10d in the first period is defined as a third sensitivity. The layer rotation is executed in such a way that the third pixel 10c exhibits the third sensitivity in the second period, that the first pixel 10a exhibits the third sensitivity in the third period, and that the second pixel 10b exhibits the third sensitivity in the fourth period.

The sensitivity to light exhibited by the third pixel 10c in the first period is defined as a fourth sensitivity. The layer rotation is executed in such a way that the first pixel 10a exhibits the fourth sensitivity in the second period, that the second pixel 10b exhibits the fourth sensitivity in the third period, and that the fourth pixel 10d exhibits the fourth sensitivity in the fourth period.

In the present embodiment, it can be said that the layer rotation is virtual rotation of a pixel layer, in other words, a unit array which is a four-pixel array including two rows and two columns. In a typical example, the layer rotation is executed in each pixel layer 10. In layer rotation according to a typical example, a cycle including the first period, the second period, the third period, and the fourth period is repeated.

The layer rotation can help provide clear images. In addition, the layer rotation executed by changing voltages makes it less likely to cause a significant increase in the size of the image sensor. This can help downsize the image sensor.

### Fifth Embodiment

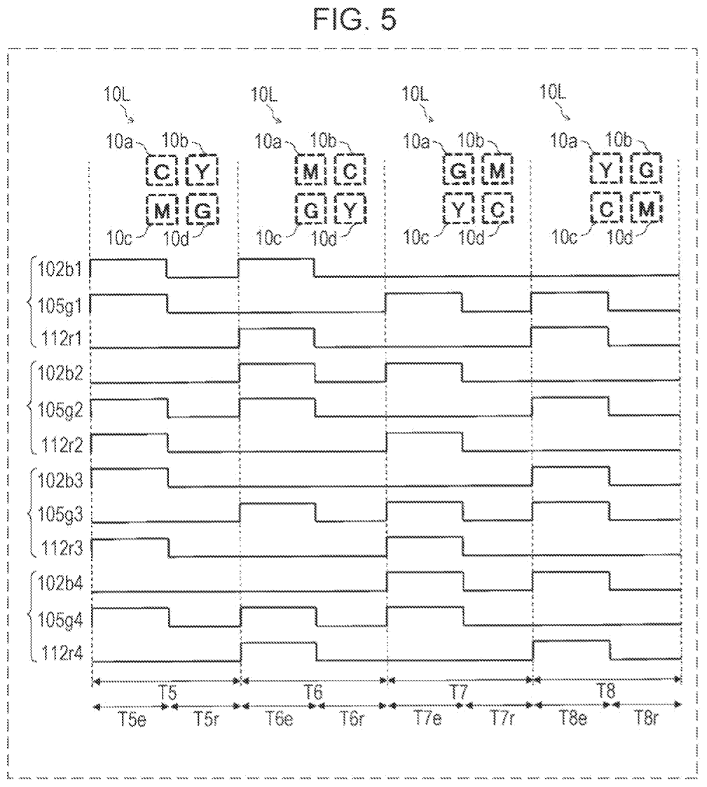

In a fifth embodiment, voltages are applied to the comb portions 102b1, 102b2, 102b3, 102b4, 105g1, 105g2, 105g3, 105g4, 112r1, 112r2, 112r3, and 112r4 in a mode different from the fourth embodiment. The following describes the waveforms of voltages applied to the comb portions 102b1, 102b2, 102b3, 102b4, 105g1, 105g2, 105g3, 105g4, 112r1, 112r2, 112r3, and 112r4 with reference to FIG. 5.

In FIG. 5, the period T5, the period T6, the period T7, and the period T8 occur in this order. The period T5 corresponds to a fifth frame. The period T6 corresponds to a sixth frame. The period T7 corresponds to a seventh frame. The period T8 corresponds to an eighth frame. In other words, the images of the fifth frame, the sixth frame, the seventh frame, and the eighth frame are in this order in time series.

The period T5 includes an exposure period T5e and a read-out period T5r in this order. The period T6 includes an exposure period T6e and a read-out period T6r in this order. The period T7 includes an exposure period T7e and a read-out period T7r in this order. The period T8 includes an exposure period T8e and a read-out period T8r in this order.

In the exposure period T5e, voltages are applied to the comb portions 102b1, 105g1, 105g2, 112r2, 102b3, 112r3, and 105g4. Thus, the first pixel 10a has sensitivity to cyan light. The second pixel 10b has sensitivity to yellow light. The third pixel 10c has sensitivity to magenta light. The fourth pixel 10d has sensitivity to green light. In the read-out period T5r, the electric charges stored in the electric-charge storage regions 108 in the exposure period T5e are read out as signals.

In the exposure period T6e, voltages are applied to the comb portions 102b1, 112r1, 102b2, 105g2, 105g3, 105g4, and 112r4. Thus, the first pixel 10a has sensitivity to magenta light. The second pixel 10b has sensitivity to cyan light. The third pixel 10c has sensitivity green light. The fourth pixel 10d has sensitivity to yellow light. In the read-out period T6r, the electric charges stored in the electric-charge storage regions 108 in the exposure period T6e are read out as signals.

In the exposure period T7e, voltages are applied to the comb portions 105g1, 102b2, 112r2, 105g3, 112r3, 102b4, and 105g4. Thus, the first pixel 10a has sensitivity to green light. The second pixel 10b has sensitivity to magenta light. The third pixel 10c has sensitivity to yellow light. The fourth pixel 10d has sensitivity to cyan light. In the read-out period T7r, the electric charges stored in the electric-charge storage regions 108 in the exposure period T7e are read out as signals.

In the exposure period T8e, voltages are applied to the comb portions 105g1, 112r1, 105g2, 102b3, 105g3, 102b4, and 112r4. Thus, the first pixel 10a has sensitivity to yellow light. The second pixel 10b has sensitivity to green light. The third pixel 10c has sensitivity to cyan light. The fourth pixel 10d has sensitivity to magenta light. In the read-out period T8r, the electric charges stored in the electric-charge storage regions 108 in the exposure period T8e are read out as signals.

Through the four frames from the period T5 to the period T8, the layer arrangement can be rotated.

The rotation of the layer arrangement can help provide clear images.

In the present embodiment, it is possible to obtain complementary color signals.

A complementary color signal can be generated also by combining two primary signals in a subsequent digital region. However, in that case, there is a possibility that the generated complementary color signal can have a noise. The noise can decrease the image quality. In contrast, in the present embodiment, complementary color signals can be generated in an analog region. This is advantageous from the viewpoint of providing high image quality.

### Sixth Embodiment

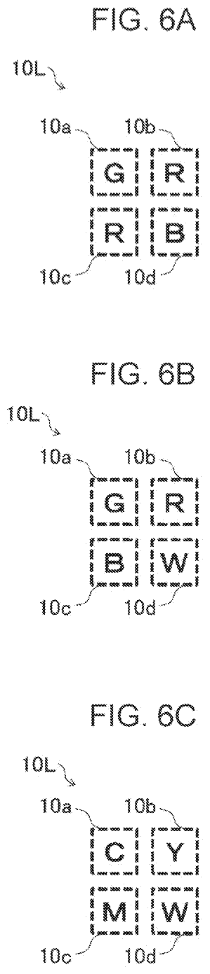

It is possible to set the sensitivities that the four pixels 10a, 10b, 10c, and 10d exhibit in a mode different from the fourth and fifth embodiments. The following describes the sensitivities that the four pixels 10a, 10b, 10c, and 10d exhibit in a sixth embodiment with reference to FIGS. 6A to 6C.

The pixel layer 10L according to the example of FIG. 6A can emphasize red light. In this example, voltages are applied to the comb portions 112r2 and 112r3 in the exposure period, and thus, the second pixel 10b and the third pixel 10c have sensitivity to red light.

Specifically, in the example of FIG. 6A, voltages are applied to the comb portions 105g1, 112r2, 112r3, and 102b4 in the exposure period. Thus, the first pixel 10a has sensitivity to green light. The second pixel 10b and the third pixel 10c have sensitivity to red light. The fourth pixel 10d has sensitivity to blue light.

The pixel layer 10L according to an example of FIG. 6B has a white pixel in addition to RGB. In this example, voltages are applied to the comb portions 102b4, 105g4, and 112r4 in the exposure period, and thus, the fourth pixel 10d has sensitivity to white light.

Specifically, in the example of FIG. 6B, voltages are applied to the comb portions 105g1, 112r2, 102b3, 102b4, 105g4, and 112r4 in the exposure period. Thus, the first pixel 10a has sensitivity to green light. The second pixel 10b has sensitivity to red light. The third pixel 10c has sensitivity blue light. The fourth pixel 10d has sensitivity to white light.

The pixel layer 10L according to an example of FIG. 6C has a white pixel in addition to the complementary colors. In this example, voltages are applied to the comb portions 102b4, 105g4, and 112r4 in the exposure period, and thus, the fourth pixel 10d has sensitivity to white light.

Specifically, in the example of FIG. 6C, voltages are applied to the comb portions 102b1, 105g1, 105g2, 112r2, 102b3, 112r3, 102b4, 105g4, and 112r4 in the exposure period. Thus, the first pixel 10a has sensitivity to cyan light. The second pixel 10b has sensitivity to yellow light. The third pixel 10c has sensitivity to magenta light. The fourth pixel 10d has sensitivity to white light.

With the example of FIG. 6A according to the sixth embodiment, it is possible to obtain a signal in which a desired color is emphasized. The examples of FIGS. 6B and 6C according to the sixth embodiment can be utilize to capture images of dark scenes.

As can be understood from the above description, in the example of FIG. 6A, the voltages of the first photoelectric conversion layer 103, the second photoelectric conversion layer 106, and the third photoelectric conversion layer 113 in each of the first pixel 10a, the second pixel 10b, the third pixel 10c, and the fourth pixel 10d are adjusted such that at least two pixels out of the first pixel 10a, the second pixel 10b, the third pixel 10c, and the fourth pixel 10d have the same sensitivity to light.

In the examples of FIGS. 6B and 6C, the voltages of the first photoelectric conversion layer 103, the second photoelectric conversion layer 106, and the third photoelectric conversion layer 113 in each of the first pixel 10a, the second pixel 10b, the third pixel 10c, and the fourth pixel 10d are adjusted such that at least one pixel out of the first pixel 10a, the second pixel 10b, the third pixel 10c, and the fourth pixel 10d has sensitivity to the light obtained by combining light in the first wavelength band, light in the second wavelength band, and light in the third wavelength band.

Note that the sixth embodiment may be combined with the technique of the layer rotation.

### Seventh Embodiment

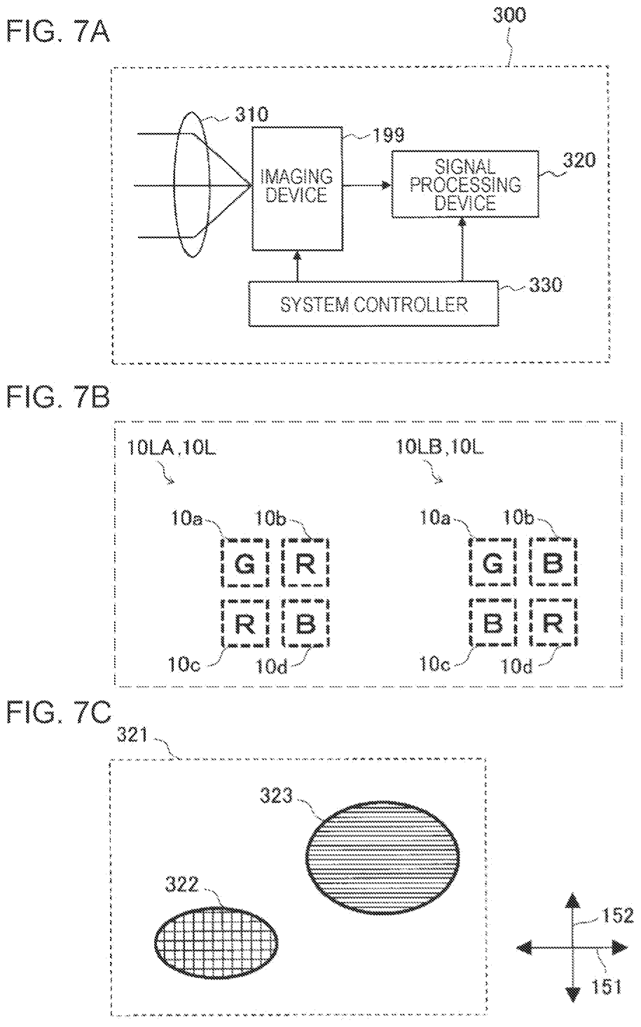

FIG. 7A shows an imaging system 300 according to a seventh embodiment.

The imaging system 300 includes an imaging device 199, a lens 310, a signal processing device 320, and a system controller 330. The lens 310 is an optical element for guiding incident light to the plurality of pixels 10 included in the imaging device 199. The imaging device 199 converts the image light formed on an imaging surface by the lens 310 into electrical signals in units of pixels and outputs the obtained image signals. The signal processing device 320 is a circuit that performs various kinds of processing on the image signals generated in the imaging device 199. The system controller 330 is a control unit that drives the imaging device 199 and the signal processing device 320. In the illustrated example, the signal processing device 320 is a camera-signal processing circuit.

FIG. 7B shows the pixel layer 10L that can be obtained in the imaging device 199 according to the present embodiment. Specifically, the left part of FIG. 7B shows the pixel layer 10L in the A frame, which is referred to as the pixel layer 10LA. The right part of FIG. 7B shows the pixel layer 10L in the B frame, which is referred to as the pixel layer 10LB.

Red light is emphasized in the A frame. The pixel layer 10LA in the A frame shown in the left part of FIG. 7B is the same as the pixel layer 10L shown in FIG. 6A.

Blue light is emphasized in the B frame. The pixel layer 10LB in the B frame shown in the right part of FIG. 7B can be obtained by adjusting the voltages of the comb portions. Specifically, voltages are applied to the comb portions 105g1, 102b2, 102b3, and 112r4 in the exposure period. Thus, the first pixel 10a has sensitivity to green light. The second pixel 10b and the third pixel 10c have sensitivity to blue light. The fourth pixel 10d has sensitivity to red light.

The signal processing device 320 combines the A frame and the B frame to generate a composite frame 321 shown in FIG. 7C. In the composite frame 321, an A region 322 is based on the A frame in which red light is emphasized. In the composite frame 321, a B region 323 is based on the B frame in which blue light is emphasized. As described above, the composite frame 321 may have a region in which red light is emphasized and a region in which blue light is emphasized, at the same time.

For example, it is conceivable in medical use that red is emphasized in an inflamed region and that blue is emphasized in a necrosed region.

In a specific example, one of the odd frame and the even frame is defined as the A frame. The other of the odd frame and the even frame is defined as the B frame.

The seventh embodiment is capable of providing an image in which different desired colors are emphasized at the same time.

As can be understood from the above description, the imaging system 300 according to the seventh embodiment includes the signal processing device 320. In each of the pixel layers 10L, at least one of the wavelength band of the light to which the first pixel 10a has sensitivity, the wavelength band of the light to which the second pixel 10b has sensitivity, the wavelength band of the light to which the third pixel 10c has sensitivity, or the wavelength band of the light to which the fourth pixel 10d has sensitivity is different between when one frame is generated and when another frame is generated. The signal processing device 320 generates a composite frame 321 by combining the one frame and the other frame. In a region 322 in the composite frame 321, an image based on the one frame appears. In another region 323 in the composite frame 321, an image based on the other frame appears. With the seventh embodiment, it is possible to make a difference in the emphasized color between a region 322 and another region 323.

In the above description, the one frame corresponds to the A frame. The other frame corresponds to the B frame. The one region 322 corresponds to the A region 322. The other region 323 corresponds to the B region 323.

Specifically, in the one region 322, an image having a larger contribution from the one frame and a smaller contribution from the other frame than in the other region 323 appears. In the other region 323, an image having a larger contribution from the other frame and a smaller contribution from the one frame than in the one region 322 appears. In the one region 322, an image having no contribution from the other frame and based on the one frame may appear. In the other region 323, an image having no contribution from the one frame and based on the other frame may appear.

In the illustrated example, the imaging device 199 has a plurality of pixel layers 10L. The plurality of pixel layers 10L are arrayed in the first direction 151 and the second direction 152. In a typical example, the signal processing device 320 generates one frame and another frame using the plurality of pixel layers 10L and then generates a composite frame 321.

As described above, the first direction 151 and the second direction 152 may be directions included in a plane perpendicular to the thickness direction of the semiconductor substrate 109. Specifically, the first direction 151 and the second direction 152 may be directions orthogonal to each other. In the present embodiment, the first direction 151 is the row direction. The second direction 152 is the column direction.

Note that the seventh embodiment may be combined with the technique of the layer rotation.

### Eighth Embodiment

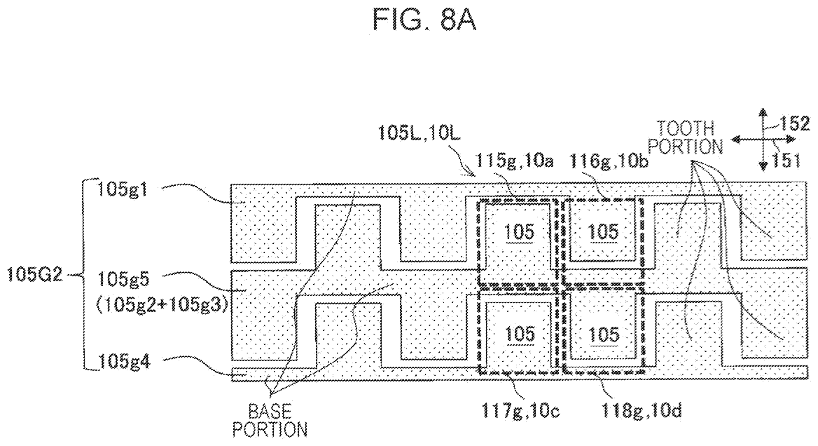

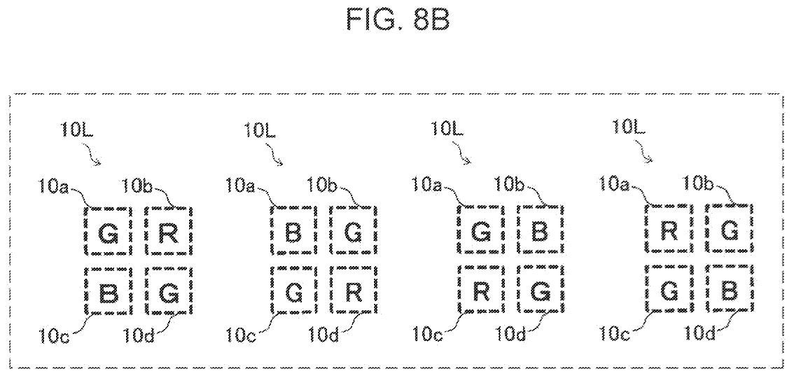

The second electrode structure can be built in a configuration different from the second electrode structure 105G of the fourth embodiment shown in FIG. 4B. The following describes the configuration of a second electrode structure 105G2 of an eighth embodiment with reference to FIG. 8A.

As in the second electrode structure 105G shown in FIG. 4B, the second electrode structure 105G2 shown in FIG. 8A includes a first comb portion 105g1, a second comb portion 105g2, a third comb portion 105g3, and a fourth comb portion 105g4. The first comb portion 105g1 and the second comb portion 105g2 engage with each other via a gap in the second direction 152 and extend in the first direction 151. The third comb portion 105g3 and the fourth comb portion 105g4 engage with each other via a gap in the second direction 152 and extend in the first direction 151.

However, the second electrode structure 105G2 shown in FIG. 8A is different from the second electrode structure 105G shown in FIG. 4B in that the second comb portion 105g2 and the third comb portion 105g3 are unified into a unified comb portion 105g5.

The first comb portion 105g1, the unified comb portion 105g5, and the fourth comb portion 105g4 are electrically separated from one another.

With the second electrode structure 105G2 shown in FIG. 8A, it is possible to obtain the pixel layer 10L in FIG. 8B. As can be seen from the comparison between FIG. 8B and FIG. 4E, the second electrode structure 105G2 shown in FIG. 8A can provide the pixel layer 10L with the same sensitivity as that obtained by the second electrode structure 105G shown in FIG. 4B.

With the eighth embodiment, it is possible to enlarge the area of the region in which the second photoelectric conversion layer 106 exhibits sensitivity by the unified comb portion 105g5 having a large area.

### Ninth Embodiment

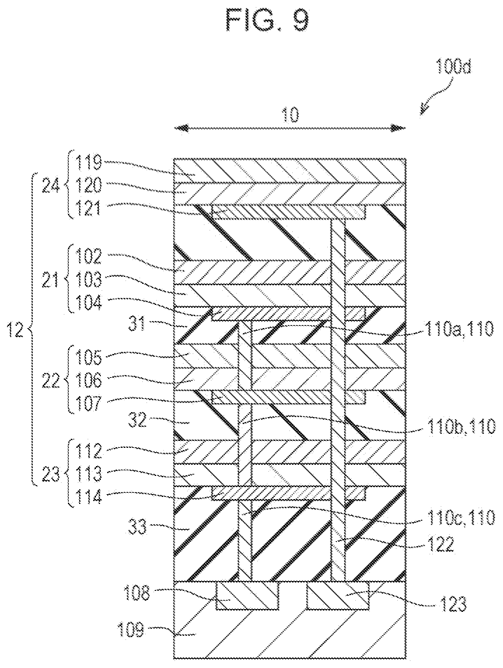

As described above, in the image sensor 100c shown in FIG. 3, the first photoelectric converter 21, the second photoelectric converter 22, and the third photoelectric converter 23 are electrically connected to the electric-charge storage region 108. An image sensor may include a photoelectric converter different from the photoelectric converters 21, 22, and 23, and the different photoelectric converter may be connected to an electric-charge storage region different from the electric-charge storage region 108. FIG. 9 shows an image sensor 100d according to a ninth embodiment.

The image sensor 100d includes a fourth photoelectric converter 24, in addition to a first photoelectric converter 21, a second photoelectric converter 22, and a third photoelectric converter 23. The first photoelectric converter 21, the second photoelectric converter 22, the third photoelectric converter 23, and the fourth photoelectric converter 24 are included in a photoelectric conversion region 12. The first photoelectric converter 21, the second photoelectric converter 22, and the third photoelectric converter 23 are located between the fourth photoelectric converter 24 and a semiconductor substrate 109. The semiconductor substrate 109 has an electric-charge storage region 123, in addition to an electric-charge storage region 108. Each pixel 10 may include the semiconductor substrate 109 having the electric-charge storage region 108 and the electric-charge storage region 123, the first photoelectric converter 21, the second photoelectric converter 22, the third photoelectric converter 23, and the fourth photoelectric converter 24.

The fourth photoelectric converter 24 includes a fourth counter electrode 119, a fourth pixel electrode 121, and a fourth photoelectric conversion layer 120. The fourth photoelectric conversion layer 120 is located between the fourth counter electrode 119 and the fourth pixel electrode 121. The fourth counter electrode 119 is electrically connected to the fourth photoelectric conversion layer 120. The fourth pixel electrode 121 is electrically connected to the fourth photoelectric conversion layer 120.

The electric-charge storage region 123 is electrically connected to the fourth pixel electrode 121.

In the example of FIG. 9, the electric charge generated by the photoelectric conversion in the fourth photoelectric converter 24 is once stored in the electric-charge storage region 123 and then read out as a signal.

In the example of FIG. 9, in each pixel 10, the electric-charge storage region 123 is electrically connected to the fourth pixel electrode 121. Specifically, in each pixel 10, the electric charge generated by the photoelectric conversion in the fourth photoelectric converter 24 is once stored in the electric-charge storage region 123 and then read out as a signal.

The image sensor 100d in FIG. 9 includes a second plug 122 different from the specific plug 110. The second plug 122 electrically connects the fourth pixel electrode 121 and the electric-charge storage region 123. Each pixel 10 may include the second plug 122.

The specific plug 110 is electrically connected to the pixel electrodes 104, 107, and 114 and the electric-charge storage region 108. However, the specific plug 110 is electrically separated from the counter electrodes 105 and 112. The specific plug 110 is also electrically separated from the fourth counter electrode 119 and the fourth pixel electrode 121.

The second plug 122 is electrically connected to the fourth pixel electrode 121 and the electric-charge storage region 123. However, the second plug 122 is electrically separated from the counter electrodes 102, 105, and 112 and the pixel electrodes 104, 107, and 114.

In the example of FIG. 9, the specific plug 110 and the second plug 122 extend along the thickness direction of the semiconductor substrate 109 in straight lines.

### Tenth Embodiment

As described above, in the image sensor 100c shown in FIG. 3, the specific plug 110 extends overall in a straight line. However, the configuration of the specific plug 110 is not limited to this one. FIG. 10 shows an image sensor 100e according to a tenth embodiment.

As in the image sensor 100c shown in FIG. 3, a specific plug 110 of the image sensor 100e shown in FIG. 10 includes a first portion 110a, a second portion 110b, and a third portion 110c. The first portion 110a extends from the second pixel electrode 107 toward the first pixel electrode 104. The second portion 110b extends from the second pixel electrode 107 toward the third pixel electrode 114. The third portion 110c extends from the third pixel electrode 114 toward the electric-charge storage region 108.

As in the image sensor 100c shown in FIG. 3, in the image sensor 100e shown in FIG. 10, the first portion 110a electrically connects the first pixel electrode 104 and the second pixel electrode 107. The second portion 110b electrically connects the second pixel electrode 107 and the third pixel electrode 114. The third portion 110c electrically connects the third pixel electrode 114 and the electric-charge storage region 108.

As in the image sensor 100c shown in FIG. 3, in the image sensor 100e shown in FIG. 10, the first portion 110a, the second portion 110b, and the third portion 110c of the specific plug 110 are in the forms of straight lines and extend along the thickness direction of the semiconductor substrate 109.

However, unlike the image sensor 100c shown in FIG. 3, in the image sensor 100e shown in FIG. 10, the end portion of the first portion 110a on the second pixel electrode 107 side and the end portion of the second portion 110b on the second pixel electrode 107 side are apart from each other in plan view. The end portion of the second portion 110b on the third pixel electrode 114 side and the end portion of the third portion 110c on the third pixel electrode 114 side are apart from each other in plan view.

Specifically, in the image sensor 100e shown in FIG. 10, the first portion 110a and the second portion 110b are apart from each other in plan view. The second portion 110b and the third portion 110c are apart from each other in plan view.

In the image sensor 100e shown in FIG. 10, the end portion of the first portion 110a on the second pixel electrode 107 side and the end portion of the third portion 110c on the third pixel electrode 114 side overlap with each other in plan view. However, the end portion of the first portion 110a on the second pixel electrode 107 side and the end portion of the third portion 110c on the third pixel electrode 114 side may be apart from each other in plan view.

Specifically, in the image sensor 100e shown in FIG. 10, the first portion 110a and the third portion 110c overlap with each other in plan view. However, the first portion 110a and the third portion 110c may be apart from each other in plan view.

With the tenth embodiment, it is possible to increase the degree of freedom in arrangement of the specific plug 110.

### Eleventh Embodiment

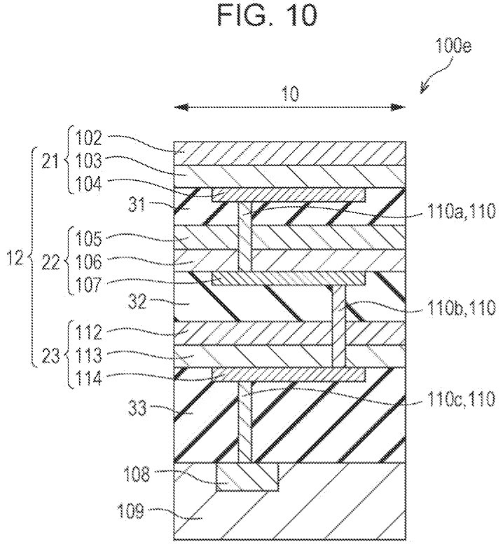

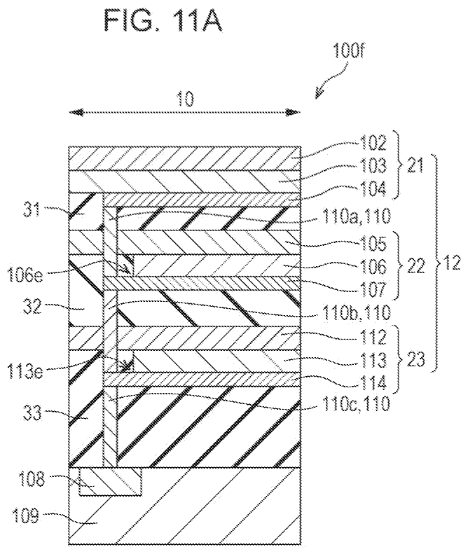

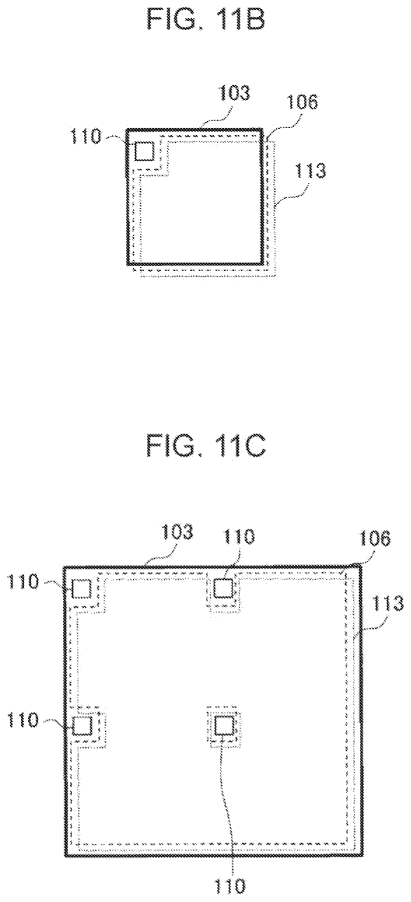

As described above, in the image sensor 100c shown in FIG. 3, the specific plug 110 passes through the through holes formed in the third photoelectric conversion layer 113 and the second photoelectric conversion layer 106. Here, the way of allocating space for the extension of the specific plug 110 is not limited to this configuration. FIGS. 11A, 11B, and 11C show an image sensor 100f according to an eleventh embodiment. FIG. 11A is a sectional view of the image sensor 100f according to the eleventh embodiment. FIG. 11B is a top view of one pixel 10 according to the eleventh embodiment. FIG. 11C is a top view of a plurality of pixels 10 according to the eleventh embodiment.

As in the image sensor 100c shown in FIG. 3, in the image sensor 100f shown in FIGS. 11A, 11B, and 11C, a specific plug 110 is electrically separated from a third counter electrode 112. The specific plug 110 is also electrically separated from a second counter electrode 105.

However, unlike the image sensor 100c shown in FIG. 3, in the image sensor 100f shown in FIGS. 11A, 11B, and 11C, the specific plug 110 is located outside the outline 106e of the second photoelectric conversion layer 106 in a section perpendicular to the thickness direction of the second photoelectric conversion layer 106. In a section perpendicular to the thickness direction of the third photoelectric conversion layer 113, the specific plug 110 is located outside the outline 113e of the third photoelectric conversion layer 113.

The feature that the specific plug 110 is located outside the outline 106e of the second photoelectric conversion layer 106 can be specifically explained as follows. Specifically, in a section extending in the directions of a plane perpendicular to the thickness direction of the second photoelectric conversion layer 106, the specific plug 110 is located outside, in the directions of the plane, the outer edge of the second photoelectric conversion layer 106 in the directions of the plane.

The feature that the specific plug 110 is located outside the outline 113e of the third photoelectric conversion layer 113 can be specifically explained as follows. Specifically, in a section extending in the directions of a plane perpendicular to the thickness direction of the third photoelectric conversion layer 113, the specific plug 110 is located outside, in the directions of the plane, the outer edge of the third photoelectric conversion layer 113 in the directions of the plane.

In the eleventh embodiment, the second photoelectric conversion layer 106 and the third photoelectric conversion layer 113 do not have to have a through hole. This makes it easy to manufacture the image sensor 100f, and this in turn can increase the reliability of the image sensor 100f.

Note that in FIGS. 11B and 11C, the position indicated by the relatively coarse dashed lines corresponds to the outline 106e of the second photoelectric conversion layer 106. The position indicated by the relatively fine dotted line corresponds to the outline 113e of the third photoelectric conversion layer 113.

### Twelfth Embodiment

In the foregoing embodiments, the first pixel electrode 104 is one continuous electrode. The first electric charge generated by the photoelectric conversion in the first photoelectric conversion layer 103 according to the electric potential difference applied between the first counter electrode 102 and the first pixel electrode 104 is collected at the first pixel electrode 104. The first pixel electrode 104 is electrically connected to the specific plug 110. The second pixel electrode 107 is one continuous electrode. The second electric charge generated by the photoelectric conversion in the second photoelectric conversion layer 106 according to the electric potential difference applied between the second counter electrode 105 and the second pixel electrode 107 is collected at the second pixel electrode 107. The second pixel electrode 107 is electrically connected to the specific plug 110. The third pixel electrode 114 is one continuous electrode. The third electric charge generated by the photoelectric conversion in the third photoelectric conversion layer 113 according to the electric potential difference applied between the third counter electrode 112 and the third pixel electrode 114 is collected at the third pixel electrode 114. The third pixel electrode 114 is electrically connected to the specific plug 110.

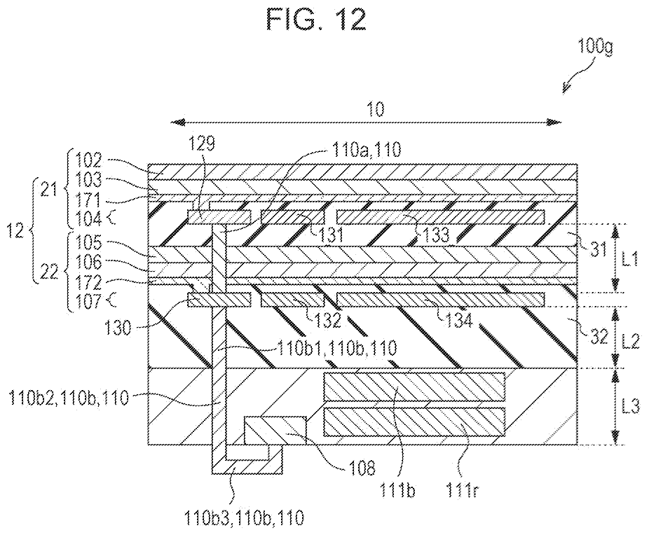

The configuration of pixel electrodes different from the above embodiment may be employed. The following describes the configuration of pixel electrodes of an image sensor 100g according to a twelfth embodiment with reference to FIG. 12.

In the image sensor 100g, the first pixel electrode 104 includes a first storage electrode 133, a first read-out electrode 129, and a first transfer electrode 131. The second pixel electrode 107 includes a second storage electrode 134, a second read-out electrode 130, and a second transfer electrode 132. The transfer electrodes 131 and 132 may be eliminated.

A first semiconductor layer 171 is located between the first pixel electrode 104 and the first photoelectric conversion layer 103. Part of the first insulation layer 31 exists between the first semiconductor layer 171 and the first pixel electrode 104. A second semiconductor layer 172 is located between the second pixel electrode 107 and the second photoelectric conversion layer 106. Part of the second insulation layer 32 exists between the second semiconductor layer 172 and the second pixel electrode 107. The semiconductor layers 171 and 172 are provided to make storage of electric charge more efficient and made of a light-transmissive semiconductor material.

The first storage electrode 133 and the first transfer electrode 131 face the first photoelectric conversion layer 103 via part of the first insulation layer 31 or via part of the first insulation layer 31 and the first semiconductor layer 171. At least part of the first read-out electrode 129 is in contact with the first photoelectric conversion layer 103 directly or via the first semiconductor layer 171. The first read-out electrode 129 is electrically connected to a specific plug 110. The first storage electrode 133, the first read-out electrode 129, and the first transfer electrode 131 are each electrically connected to not-illustrated wiring. A desired voltage may be applied to each of the first storage electrode 133, the first read-out electrode 129, and the first transfer electrode 131. The first storage electrode 133 may function as an electric-charge storage electrode for attracting, according to the applied voltage, the electric charge generated in the first photoelectric conversion layer 103 and storing the electric charge in the first photoelectric conversion layer 103. The first transfer electrode 131 is located between the first storage electrode 133 and the first read-out electrode 129 in plan view. The first transfer electrode 131 plays a role of damming the stored electric charge and controlling transfer of the electric charge. By controlling the voltages applied to the first storage electrode 133, the first read-out electrode 129, and the first transfer electrode 131, the electric charge generated in the first photoelectric conversion layer 103 can be stored inside the first photoelectric conversion layer 103 or at the interface of the first photoelectric conversion layer 103 or taken out the generated electric charge to the electric-charge storage region 108. These explanations of the first pixel electrode 104 can be applied to the second pixel electrode 107 by replacing “the first” with “the second”.

The above explanations of the first pixel electrode 104 and the second pixel electrode 107 can be applied to the third pixel electrode 114 in the foregoing embodiment.

As can be understood from the above description, in the image sensor 100g of the present embodiment, the first photoelectric conversion layer 103 generates first electric charge by photoelectric conversion. The second photoelectric conversion layer 106 generates second electric charge by photoelectric conversion. The first pixel electrode 104 includes the first read-out electrode 129 and the first storage electrode 133 that causes the first photoelectric conversion layer 103 to store the first electric charge. The second pixel electrode 107 includes the second read-out electrode 130 and the second storage electrode 134 that causes the second photoelectric conversion layer 106 to store the second electric charge. The electric-charge storage region 108 is electrically connected to the first read-out electrode 129 and the second read-out electrode 130. Specifically, the specific plug 110 electrically connects the first read-out electrode 129, the second read-out electrode 130, and the electric-charge storage region 108.

The structure of electrodes according to the present embodiment makes it possible to collect and transfer efficiently the electric charge generated in the photoelectric conversion layers, leading to improvement in the sensitivity. The structure of the electrodes according to the present embodiment can be applied all the foregoing embodiments.

### (Other Information)

Features of each embodiment described above, features applicable to each embodiment, and the like will be further described below.

The image sensor may be of a front side illumination (FSI) type or may be of a back side illumination (BSI) type. The image sensor 100a shown in FIG. 1B, the image sensor 100c shown in FIG. 3, the image sensor 100d shown in FIG. 9, the image sensor 100e shown in FIG. 10, and the image sensor 100f shown in FIG. 11A are of a front side illumination type. The image sensor 100b shown in FIGS. 2A and 2C and the image sensor 100g shown in FIG. 12 are of a back side illumination type.

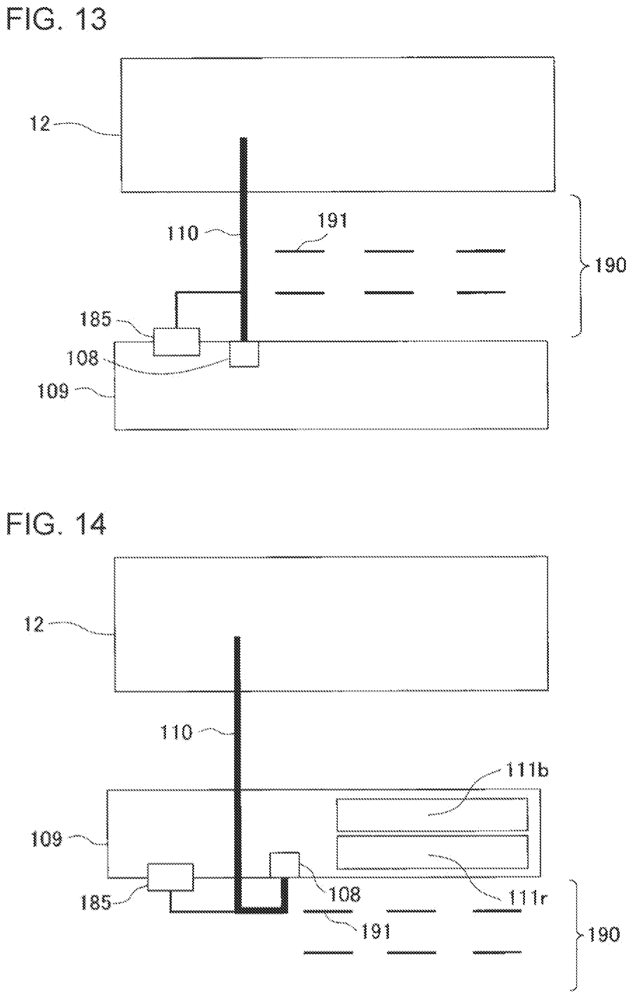

A feature applicable to an image sensor of a front side illumination type is shown in FIG. 13. An image sensor in an example of FIG. 13 includes a not-illustrated microlens, a photoelectric conversion region 12, a wiring layer 190, and a semiconductor substrate 109 arranged in this order. The wiring layer 190 has wiring 191 in an insulation material.

A feature applicable to an image sensor of a back side illumination type is shown in FIG. 14. An image sensor in an example of FIG. 14 includes a not-illustrated microlens, a photoelectric conversion region 12, a semiconductor substrate 109, and a wiring layer 190 arranged in this order. The wiring layer 190 has wiring 191 in an insulation material.

The semiconductor substrate 109 has photodiodes 111b and 111r in its inside. In the image sensor of a back side illumination type in the example of FIG. 14, light illumination to the photodiodes 111b and 111r are not blocked by the wiring 191 of the wiring layer 190. In an image sensor of a back side illumination type, wiring can be located between the photoelectric conversion region 12 and the semiconductor substrate 109.

In the examples of FIGS. 13 and 14, the configuration may be such that the specific plug 110 includes the wiring 191 of the wiring layer 190 or that the specific plug 110 does not include the wiring 191 of the wiring layer 190.

In the examples of FIGS. 13 and 14, the gate electrode of an amplification transistor 185 is electrically connected to the electric-charge storage region 108 by using the wiring 191 of the wiring layer 190. A signal according to the electric charge stored in the electric-charge storage region 108 is generated by the amplification transistor 185.

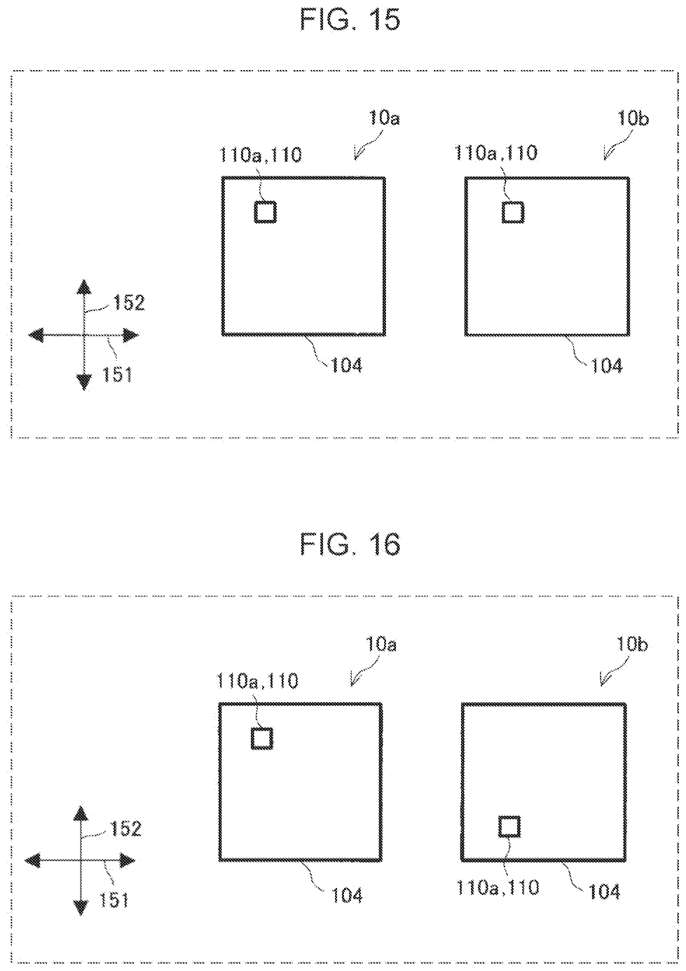

The specific plug 110 may be arranged as described below with reference to FIGS. 15 and 16.

In the examples of FIGS. 15 and 16, a specific plug 110 includes a first portion 110a. The first portion 110a extends from a first pixel electrode 104 to a second pixel electrode 107. There are a plurality of pixels each including an electric-charge storage region 108, the specific plug 110, a first photoelectric converter 21, and a second photoelectric converter 22. The plurality of pixels include a first pixel 10a and a second pixel 10b. The first pixels 10a and the second pixels 10b are next to each other in plan view in a first direction 151.

In the example of FIG. 15, the position in the second direction 152 of the first portion 110a of the first pixel 10a and the position in the second direction 152 of the first portion 110a of the second pixel 10b are the same in plan view. This is advantageous from the viewpoint of manufacturing the first pixel 10a and the second pixel 10b uniformly. The position in the second direction 152 of a second portion 110b of the first pixel 10a and the position in the second direction 152 of a second portion 110b of the second pixel 10b may be the same in plan view. The position in the second direction 152 of a third portion 110c of the first pixel 10a and the position in the second direction 152 of a third portion 110c of the second pixel 10b are the same in plan view.

In the example of FIG. 16, the position in the second direction 152 of the first portion 110a of the first pixel 10a and the position in the second direction 152 of the first portion 110a of the second pixel 10b are different in plan view. The example of FIG. 16 increases the degree of freedom in arrangement of the first portion 110a. The position in the second direction 152 of a second portion 110b of the first pixel 10a and the position in the second direction 152 of a second portion 110b of the second pixel 10b may be different in plan view. The position in the second direction 152 of a third portion 110c of the first pixel 10a and the position in the second direction 152 of a third portion 110c of the second pixel 10b may be different in plan view.

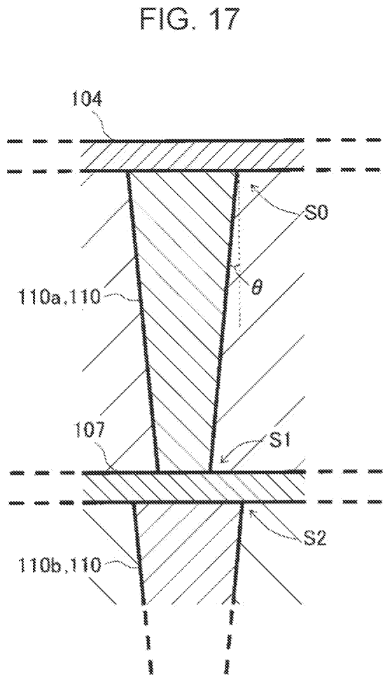

The specific plug 110 may have a shape described below with reference to FIG. 17.

In the example of FIG. 17, a specific plug 110 includes a first portion 110a and a second portion 110b. The first portion 110a extends from a first pixel electrode 104 to a second pixel electrode 107. The second portion 110b of the specific plug 110 extends from the second pixel electrode 107 toward an electric-charge storage region 108. The sectional area of the first portion 110a continuously reduces in the region of the first portion 110a including the end portion on the second pixel electrode 107 side as the position comes closer from the first pixel electrode 104 to the second pixel electrode 107. The sectional area S2 of the second portion 110b at the end portion on the second pixel electrode 107 side is larger than the sectional area S1 of the first portion 110a at the end portion on the second pixel electrode 107 side. In the case in which the sectional area of the first portion 110a changes as described above, the relationship S2>S1 can contribute to increasing the overall uniformity of the sectional area of the specific plug 110. In the example of FIG. 17, the sectional area of the second portion 110b continuously reduces in the region of the second portion 110b including the end portion on the second pixel electrode 107 side as the position comes closer from the second pixel electrode 107 to the electric-charge storage region 108. Note that the sectional area of the first portion 110a is the one in a section perpendicular to the thickness direction of the semiconductor substrate 109. In the region referred to in the above explanation, the sectional area of the second portion 110b is the one in a section perpendicular to the thickness direction of the semiconductor substrate 109.

In the manufacturing process for the image sensor according to an example, a hole is formed by dry etching, and the first portion 110a is formed by filling the hole with a conductor. In this example, there are cases in which the direction in which the side surface of the hole extends is not the same as the thickness direction of the semiconductor substrate 109 in a strict sense, and in which the diameter of the hole becomes smaller as the position come closer to the semiconductor substrate 109. For example, in such a case, the sectional area of the first portion 110a can change as described above.

In the example of FIG. 17, in the section extending in the thickness direction of the semiconductor substrate 109, the first portion 110a and the second portion 110b have a tapered shape the diameter of which reduces as the position comes closer to the semiconductor substrate 109 in the region that the above explanation refers to.

In the example of FIG. 17, specifically, the sectional area of the first portion 110a continuously reduces from the end portion on the first pixel electrode 104 side to the end portion on the second pixel electrode 107 side, in other words, in the entire first portion 110a as the position comes closer from the first pixel electrode 104 to the second pixel electrode 107. In the section extending in the thickness direction of the semiconductor substrate 109, the first portion 110a has a tapered shape the diameter of which reduces as the position comes closer to the semiconductor substrate 109 from the end portion on the first pixel electrode 104 side to the end portion on the second pixel electrode 107 side.

The ratio S2/S1 of the sectional area S2 of the end portion of the second portion 110b on the second pixel electrode 107 side relative to the sectional area S1 of the end portion of the first portion 110a on the second pixel electrode 107 side is, for example, higher than 1 and lower than 1.2.

In the section extending in the thickness direction of the semiconductor substrate 109, the divergence angle θ of the direction in which the side surface of the first portion 110a extends relative to the thickness direction of the semiconductor substrate 109 is, for example, larger than 0° and smaller than 20°. The same can be applied to the divergence angle of the direction in which the side surface of the second portion 110b extends relative to the thickness direction of the semiconductor substrate 109. Note that the divergence angle θ is exaggerated in the illustration of FIG. 17.

The sectional area S0 of the first portion 110a at the end portion on the first pixel electrode 104 side may be larger than the sectional area S2 of the second portion 110b at the end portion on the second pixel electrode 107 side. The sectional area S0 may be equal to the sectional area S2. The sectional area S0 may be smaller than the sectional area S2.

The specific plug 110 may have the dimension described below with reference to FIGS. 1B, 2A, 2C, and 12. In the following, the terms “a first length L1”, “a second length L2”, and “a third length L3” are used.

A first length L1 is the length of the portion of the specific plug 110 from the first pixel electrode 104 to the second pixel electrode 107. Specifically, the first length L1 is the length of the portion of the specific plug 110 from the main surface of the first pixel electrode 104 on the second pixel electrode 107 side to the main surface of the second pixel electrode 107 on the first pixel electrode 104 side.

In the examples of FIGS. 1B, 2A, 2C, and 12, the length of the first portion 110a may correspond to the first length L1.

A second length L2 is the length of the portion of the specific plug 110 from the second pixel electrode 107 to the semiconductor substrate 109. Specifically, the second length L2 is the length of the portion of the specific plug 110 from the main surface of the second pixel electrode 107 on the semiconductor substrate 109 side to the main surface of the semiconductor substrate 109 on the second pixel electrode 107 side.

In the example of FIG. 1B, the length of the second portion 110b may correspond to the second length L2. In the examples in FIGS. 2A, 2C, and 12, the length of the portion 110b1 of the second portion 110b may correspond to the second length L2.

A third length L3 is the length of the portion of the specific plug 110 extending inside the semiconductor substrate 109. In the examples in FIGS. 2A, 2C, and 12, the length of the portion 110b2 of the second portion 110b may correspond to the third length L3.

In an example, the first length L1 is larger than the second length L2. If L1>L2, the first length L1 is long, and this makes it easy to employ a configuration in which an enough distance is allocated between the first pixel electrode 104 and the second pixel electrode 107. In other words, the relationship L1>L2 is compatible with the configuration in which an enough distance is allocated between the first pixel electrode 104 and the second pixel electrode 107. Thus, the relationship L1>L2 is advantageous from the viewpoint of reducing the coupling between the pixel electrodes 31 and 32.

In an example, the first length L1 is shorter than the second length L2. If L1<L2, it is easy to shorten L1. This makes it easy to reduce the difference between the parasitic capacitance of the electrical path from the first pixel electrode 104 to the electric-charge storage region 108 and the parasitic capacitance of the electrical path from the second pixel electrode 107 to the electric-charge storage region 108. In particular, in this configuration in which the electric-charge storage region 108 is electrically connected to the first pixel electrode 104 and the second pixel electrode 107, there is a possibility that a noise caused by the parasitic capacitance related to the first length L1 can be superimposed on the signal electric charge from the second pixel electrode. The relationship L1<L2 makes it possible to reduce the noise superimposed on the signal electric charge from the second pixel electrode 107. If L1<L2, L1 is short, and this makes it easy to employ a configuration in which the first photoelectric conversion layer 103 and the second photoelectric conversion layer 106 are close. In other words, the relationship L1<L2 is compatible with the configuration in which the first photoelectric conversion layer 103 and the second photoelectric conversion layer 106 are close. Thus, the relationship L1<L2 makes it easy to prevent the light obliquely incident on a pixel and having passed through the first photoelectric conversion layer 103 from entering the second photoelectric conversion layer 106 of another adjoining pixel.

In an example, the third length L3 is larger than the first length L1 or the second length L2. The configuration in which L3>L1 or L3>L2 holds is compatible with the configuration in which the semiconductor substrate 109 is thick. Thus, the configuration in which L3>L1 or L3>L2 holds is advantageous from the viewpoint of allocating enough space to the photodiodes 111b and 111r arranged inside the semiconductor substrate 109. The third length L3 may be longer than the sum of the first length L1 and the second length L2.

The imaging device according to the present disclosure can be utilized in various camera systems and sensor systems such as digital still cameras, medical cameras, surveillance cameras, in-vehicle cameras, digital single-lens reflex cameras, and digital mirrorless single-lens cameras.

What is claimed is:

1. An image sensor comprising:
a semiconductor substrate having an electric-charge storage region;
a first photoelectric converter including a first counter electrode, a first pixel electrode, and a first photoelectric conversion layer located between the first counter electrode and the first pixel electrode; and
a second photoelectric converter including a second counter electrode, a second pixel electrode, and a second photoelectric conversion layer located between the second counter electrode and the second pixel electrode, the second photoelectric converter being located between the first photoelectric converter and the semiconductor substrate, wherein
the electric-charge storage region is electrically connected to the first pixel electrode and the second pixel electrode.

2. The image sensor according to claim 1, further comprising
a plug, wherein
the plug electrically connects the first pixel electrode, the second pixel electrode, and the electric-charge storage region.

3. The image sensor according to claim 2, wherein
the plug includes a first portion and a second portion,
the first portion of the plug extends from the second pixel electrode toward the first pixel electrode,
the second portion of the plug extends from the second pixel electrode toward the electric-charge storage region, and
an end portion of the first portion on a second pixel electrode side and an end portion of the second portion on the second pixel electrode side are apart from each other in plan view.

4. The image sensor according to claim 2, wherein
the plug is electrically separated from the second counter electrode.

5. The image sensor according to claim 2, wherein
the plug is located outside the outline of the second photoelectric conversion layer in a section perpendicular to a thickness direction of the second photoelectric conversion layer.

6. The image sensor according to claim 2, wherein
the plug includes a first portion,
the first portion extends from the first pixel electrode to the second pixel electrode,
the image sensor includes a plurality of pixels each including the electric-charge storage region, the plug, the first photoelectric converter, and the second photoelectric converter,
the plurality of pixels include a first pixel and a second pixel, and
in plan view,
the first pixel and the second pixel are next to each other in a first direction, and
a position in a second direction of the first portion of the first pixel and a position in the second direction of the first portion of the second pixel are same.

7. The image sensor according to claim 2, wherein
the plug includes a first portion,
the first portion extends from the first pixel electrode to the second pixel electrode,
the image sensor includes a plurality of pixels each including the electric-charge storage region, the plug, the first photoelectric converter, and the second photoelectric converter,
the plurality of pixels include a first pixel and a second pixel, and
in plan view,
the first pixel and the second pixel are next to each other in a first direction, and
a position in a second direction of the first portion of the first pixel and a position in the second direction of the first portion of the second pixel are different.

8. The image sensor according to claim 2, wherein
the plug includes a first portion and a second portion,
the first portion extends from the first pixel electrode to the second pixel electrode,
the second portion of the plug extends from the second pixel electrode toward the electric-charge storage region,
a sectional area of the first portion continuously reduces in a region of the first portion including an end portion on a second pixel electrode side as a position comes closer from the first pixel electrode to the second pixel electrode, and
a sectional area of the second portion at an end portion on the second pixel electrode side is larger than the sectional area of the first portion at the end portion on the second pixel electrode side.

9. The image sensor according to claim 8, wherein
the sectional area of the first portion continuously reduces from an end portion on a first pixel electrode side to the end portion on the second pixel electrode side as the position comes closer from the first pixel electrode to the second pixel electrode.

10. The image sensor according to claim 8, wherein
a ratio of the sectional area of the second portion at the end portion on the second pixel electrode side relative to the sectional area of the first portion at the end portion on the second pixel electrode side is higher than 1 and lower than 1.2.

11. The image sensor according to claim 2, wherein
in a case in which a length of a portion of the plug from the first pixel electrode to the second pixel electrode is defined as a first length, and
a length of a portion of the plug from the second pixel electrode to the semiconductor substrate is defined as a second length,
the first length is longer than the second length.

12. The image sensor according to claim 2, wherein
in a case in which a length of a portion of the plug from the first pixel electrode to the second pixel electrode is defined as a first length, and
a length of a portion of the plug from the second pixel electrode to the semiconductor substrate is defined as a second length,
the first length is shorter than the second length.

13. The image sensor according to claim 2, wherein
in a case in which a length of a portion of the plug from the first pixel electrode to the second pixel electrode is defined as a first length,
a length of a portion of the plug from the second pixel electrode to the semiconductor substrate is defined as a second length, and
a length of a portion of the plug extending inside the semiconductor substrate is defined as a third length,
the third length is longer than the first length or the second length.

14. The image sensor according to claim 13, wherein
the third length is longer than a sum of the first length and the second length.

15. The image sensor according to claim 1, wherein
the image sensor is of a back side illumination type.

16. The image sensor according to claim 1, wherein
the first photoelectric conversion layer generates first electric charge by photoelectric conversion,
the second photoelectric conversion layer generates second electric charge by photoelectric conversion,
the first pixel electrode includes a first read-out electrode and a first storage electrode that causes the first photoelectric conversion layer to store the first electric charge,
the second pixel electrode includes a second read-out electrode and a second storage electrode that causes the second photoelectric conversion layer to store the second electric charge, and
the electric-charge storage region is electrically connected to the first read-out electrode and the second read-out electrode.

17. The image sensor according to claim 1, wherein
the first photoelectric conversion layer performs photoelectric conversion of light in a first wavelength band, and
the second photoelectric conversion layer performs photoelectric conversion of light in a second wavelength band.

18. An imaging device comprising:
the image sensor according to claim 1; and
a voltage supply circuit that adjusts voltages of the first counter electrode and the second counter electrode.

19. The imaging device according to claim 18, wherein
the voltage supply circuit includes a variable voltage source connected to the first counter electrode and the second counter electrode.

20. The imaging device according to claim 18, wherein
the voltage supply circuit includes
a first variable voltage source connected to the second counter electrode, and
a second variable voltage source connected to the first counter electrode.

21. The imaging device according to claim 18, wherein
the voltage supply circuit makes, by adjusting voltages of the first counter electrode and the second counter electrode,
a first state in which the photoelectric conversion in the first photoelectric conversion layer is permitted, and the photoelectric conversion in the second photoelectric conversion layer is prohibited and
a second state in which the photoelectric conversion in the first photoelectric conversion layer is prohibited, and the photoelectric conversion in the second photoelectric conversion layer is permitted.

22. The imaging device according to claim 21, comprising
a plurality of pixels each including the electric-charge storage region, the first photoelectric converter, and the second photoelectric converter, wherein
the plurality of pixels include a first pixel and a second pixel, and
at first time,
the first pixel is put in the first state, and
the second pixel is put in the second state.

23. The imaging device according to claim 22, wherein
at second time,
the first pixel is put in the second state, and
the second pixel is put in the first state.

24. The image sensor according to claim 1, further comprising
a third photoelectric converter including a third counter electrode, a third pixel electrode, and a third photoelectric conversion layer located between the third counter electrode and the third pixel electrode, the third photoelectric converter being located between the second photoelectric converter and the semiconductor substrate, wherein
the first photoelectric conversion layer performs photoelectric conversion of light in a first wavelength band,
the second photoelectric conversion layer performs photoelectric conversion of light in a second wavelength band,
the third photoelectric conversion layer performs photoelectric conversion of light in a third wavelength band,
the image sensor includes a plurality of pixels each including the electric-charge storage region, the first photoelectric converter, the second photoelectric converter, and the third photoelectric converter,
the plurality of pixels include a first pixel, a second pixel a third pixel, and a fourth pixel,
the first pixel, the second pixel, the third pixel, and the fourth pixel form a pixel layer, and
in plan view,
the first pixel and the second pixel are next to each other in a first direction,
the third pixel and the fourth pixel are next to each other in the first direction,
the first pixel and the third pixel are next to each other in a second direction, and
the second pixel and the fourth pixel are next to each other in the second direction.

25. An imaging device comprising:
the image sensor according to claim 24, and
a voltage supply circuit, wherein
by changing voltages of the first counter electrode, the second counter electrode, and the third counter electrode in each of the first pixel, the second pixel, the third pixel, and the fourth pixel with the voltage supply circuit, layer rotation is executed such that
sensitivity to light exhibited by the first pixel in a first period is exhibited by the second pixel in a second period following the first period, exhibited by the fourth pixel in a third period following the second period, and exhibited by the third pixel in a fourth period following the third period,
sensitivity to light exhibited by the second pixel in the first period is exhibited by the fourth pixel in the second period, exhibited by the third pixel in the third period, and exhibited by the first pixel in the fourth period,
sensitivity to light exhibited by the fourth pixel in the first period is exhibited by the third pixel in the second period, exhibited by the first pixel in the third period, and exhibited by the second pixel in the fourth period, and
sensitivity to light exhibited by the third pixel in the first period, exhibited by the first pixel in the second period, exhibited by the second pixel in the third period, and exhibited by the fourth pixel in the fourth period.

26. An imaging system comprising:
the image sensor according to claim 24; and
a signal processing device, wherein
the pixel layer includes a plurality of pixel layers,
in each of the pixel layers, at least one of a wavelength band of light to which the first pixel has sensitivity, a wavelength band of light to which the second pixel has sensitivity, a wavelength band of light to which the third pixel has sensitivity, or a wavelength band of light to which the fourth pixel has sensitivity is different between when a frame is generated and when a different frame is generated,
the signal processing device generates a composite frame in which the frame and the different frame are combined,
in a region of the composite frame, an image based on the frame appears, and
in another region of the composite frame, an image based on the different frame appears.
